(19) United States
(12) Patent Application Publication
(10) Pub. No.: US 2025/0344390 A1
(43) Pub. Date: Nov. 6, 2025

(54) CONTINUITY IN MEMORY ARRAYS

(71) Applicant: Micron Technology, Inc., Boise, ID (US)

(72) Inventors: Dae Hong Eom, Singapore (SG); Yuan Fang, Singapore (SG)

(21) Appl. No.: 19/182,521

(22) Filed: Apr. 17, 2025

Related U.S. Application Data
(60) Provisional application No. 63/641,254, filed on May 1, 2024.

(51) Int. Cl. H10B 43/27; H10B 41/27

(52) U.S. Cl. CPC H10B 43/27; H10B 41/27

(57) ABSTRACT

Methods, systems, and devices for improving continuity in memory arrays are described. A stack of materials may be formed into a continuous memory channel and connecting channel. For example, the stack may include a set of oxide layers and metal layers. A first stack may be formed. A pillar may extend through the first stack. A recess may be formed in a first layer of the pillar. A second stack may be formed on top of the first stack and the recess, and a cavity may extend through the second stack. Protective liners may be formed along the cavity and may protect various portions of the stack as materials are removed from the recess, pillar, and cavity to form a single pillar through both stacks. The protective liners may be removed and a conductive liner may be deposited along sidewalls of the pillar to form a continuous conductive channel.

### CROSS REFERENCE

The present Application for Patent claims priority to U.S. Patent Application No. 63/641,254 by Eom et al., entitled “IMPROVING CONTINUITY IN MEMORY ARRAYS,” filed May 1, 2024, which is assigned to the assignee hereof, and which is expressly incorporated by reference in its entirety herein.

### TECHNICAL FIELD

The following relates to one or more systems for memory, including improving continuity in memory arrays.

### BACKGROUND

Memory devices are widely used to store information in various electronic devices such as computers, user devices, wireless communication devices, cameras, digital displays, and the like. Information is stored by programming memory cells within a memory device to various states. For example, binary memory cells may be programmed to one of two supported states, often corresponding to a logic 1 or a logic 0. In some examples, a single memory cell may support more than two possible states, any one of which may be stored by the memory cell. To access information stored by a memory device, a component may read (e.g., sense, detect, retrieve, identify, determine, evaluate) the state of one or more memory cells within the memory device. To store information, a component may write (e.g., program, set, assign) one or more memory cells within the memory device to corresponding states.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), 3-dimensional cross-point memory (3D cross point), not-or (NOR) and not-and (NAND) memory devices, and others. Memory devices may be described in terms of volatile configurations or non-volatile configurations. Volatile memory cells (e.g., DRAM) may lose their programmed states over time unless they are periodically refreshed by an external power source. Non-volatile memory cells (e.g., NAND) may maintain their programmed states for extended periods of time even in the absence of an external power source.

### BRIEF DESCRIPTION OF THE DRAWINGS

FIG. 1 shows an example of a system that supports improving continuity in memory arrays in accordance with examples as disclosed herein.

FIGS. 2A through 2G show examples of fabrication operations that support improving continuity in memory arrays in accordance with examples as disclosed herein.

FIGS. 3A through 3G show examples of fabrication operations that support improving continuity in memory arrays in accordance with examples as disclosed herein.

FIGS. 4A through 4G show examples of fabrication operations that support improving continuity in memory arrays in accordance with examples as disclosed herein.

FIGS. 5A through 5D show examples of fabrication operations that support improving continuity in memory arrays in accordance with examples as disclosed herein.

FIGS. 6 and 7 show flowcharts illustrating a method or methods that support improving continuity in memory arrays in accordance with examples as disclosed herein.

### DETAILED DESCRIPTION

Some memory arrays (e.g., not-and (NAND) arrays) may be manufactured using a process that includes forming a stack of materials, where the stack of materials may have an array portion, a staircase portion, and a boundary portion between the array portion and the staircase portion. The stack of materials may include alternating oxide and nitride layers (e.g., levels). A memory channel may be formed within the array portion of the stack of materials. The memory channel may be coupled with a set of memory cells that are positioned vertically along the memory channel. In some examples, a metallization procedure (e.g., replacement gate procedure) may be performed, where, during the metallization procedure, the nitride layers may be removed to form a set of cavities (in place of the vacated nitride layers) and subsequently metal may be deposited into the set of cavities to form a set of word lines, such that the memory cells within the memory channel may also be coupled to respective word lines.

In some examples, the memory channel may be coupled with a digit line via a second channel, which may be referred to as a select gate. A connection between the digit line and the memory channel may be associated with relatively high resistance, discontinuity, or both, in some cases. For example, when forming a memory channel, some processes may deposit a first conductive liner within the memory channel, and may subsequently deposit a second conductive liner within the second channel and within a junction region (e.g., a cap) that connects the memory channel with the second channel, such that the second conductive liner may contact the first conductive liner at one or more contact points between the memory channel and the junction region. The resulting connection between the memory channel and the second channel may be associated with connectivity issues and increased resistance. For example, it may be difficult to form a reliable contact point between the first and second conductive liners, which may reduce performance and reliability in accessing the memory cells.

Techniques described herein provide for an improved memory channel connection. For example, the described techniques provide for a refined manufacturing process to form a continuous conductive liner within a memory channel and a junction region, which may provide for improved connectivity and reliability of the memory device. The described techniques provide for an initial deposition of a protective liner in a bottom portion of a stack that is associated with the memory channel. A protective liner may subsequently be deposited in a top portion of the stack that is associated with the second connecting channel while a cavity for a resulting pillar and junction region through two stacks of memory materials are etched. The protective liner may be removed from both stacks of memory material in one removal process before a conductive liner is deposited throughout the cavity as a whole in one deposition process. That is, the conductive liner may be deposited continuously along sidewalls of the memory channel, the junction region, and the second channel. The single deposition process may provide for a seamless and continuous conductive liner throughout the connection, which may improve reliability and continuity of current communicated via the channel by reducing resistance and potentially poor connection points, among other possibilities.

In addition to applicability in memory systems as described herein, techniques for improving continuity in memory arrays may be generally implemented to improve the sustainability of various electronic devices and systems. As the use of electronic devices has become even more widespread, the quantity of energy used and harmful emissions associated with production of electronic devices and device operation has increased. Further, the amount of waste (e.g., electronic waste) associated with disposal of electronic devices may also pose environmental concerns. Implementing the techniques described herein may improve the impact related to electronic devices by improving continuity between connections within the memory array, which may extend the life of electronic devices and thereby reduce electronic waste, among other benefits. Additionally, or alternatively, the deposition of one or more protective liners as described herein may provide for reduction of excess oxide materials in a connection region, which may further reduce unnecessary waste and improve the life of electronic devices, among other benefits.

Features of the disclosure are illustrated and described in the context of systems, devices, and circuits. Features of the disclosure are further illustrated and described in the context of fabrication operations and flowcharts.

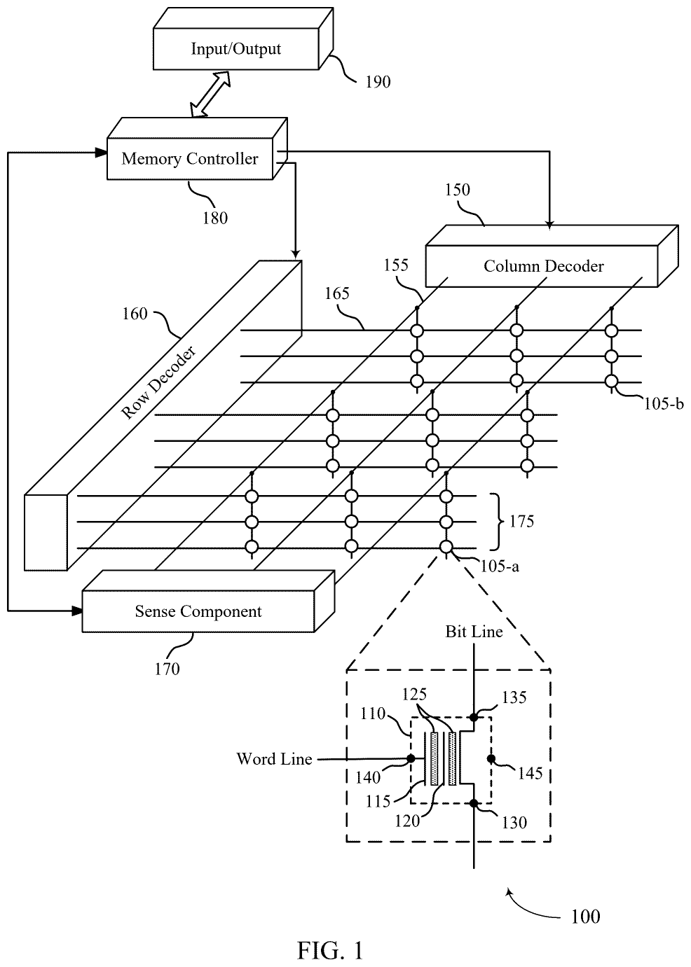

FIG. 1 shows an example of a memory device 100 that supports improving continuity in memory arrays in accordance with examples as disclosed herein. FIG. 1 is an illustrative representation of various components and features of the memory device 100. As such, the components and features of the memory device 100 are shown to illustrate functional interrelationships, and not necessarily physical positions within the memory device 100. Further, although some elements included in FIG. 1 are labeled with a numeric indicator, some other corresponding elements are not labeled, even though they are the same or would be understood to be similar, in an effort to increase visibility and clarity of the depicted features.

The memory device 100 may include one or more memory cells 105, such as memory cell 105-a and memory cell 105-b. In some examples, a memory cell 105 may be a NAND memory cell, such as in the blow-up diagram of memory cell 105-a. Each memory cell 105 may be programmed to store a logic value representing one or more bits of information. In some examples, a single memory cell 105—such as a memory cell 105 configured as a single-level cell (SLC)—may be programmed to one of two supported states and thus may store one bit of information at a time (e.g., a logic 0 or a logic 1). In some other examples, a single memory cell 105—such a memory cell 105 configured as a multi-level cell (MLC), a tri-level cell (TLC), a quad-level cell (QLC), or other type of multiple-level memory cell 105—may be programmed to one state of more than two supported states and thus may store more than one bit of information at a time. In some cases, a multiple-level memory cell 105 (e.g., an MLC memory cell, a TLC memory cell, a QLC memory cell) may be physically different than an SLC cell. For example, a multiple-level memory cell 105 may use a different cell geometry or may be fabricated using different materials. In some examples, a multiple-level memory cell 105 may be physically the same or similar to an SLC cell, and other circuitry in a memory block (e.g., a controller, sense amplifiers, drivers) may be configured to operate (e.g., read and program) the memory cell as an SLC cell, or as an MLC cell, or as a TLC cell, etc.

In some NAND memory arrays, each memory cell 105 may be illustrated as a transistor that includes a charge trapping structure (e.g., a floating gate, a replacement gate, a dielectric material) for storing an amount of charge representative of a logic value. For example, the blow-up in FIG. 1 illustrates a NAND memory cell 105-a that includes a transistor 110 (e.g., a metal-oxide-semiconductor (MOS) transistor) that may be used to store a logic value. The transistor 110 may include a control gate 115 and a charge trapping structure 120 (e.g., a floating gate, a replacement gate), where the charge trapping structure 120 may, in some examples, be between two portions of dielectric material 125. The transistor 110 also may include a first node 130 (e.g., a source or drain) and a second node 135 (e.g., a drain or source). A logic value may be stored in transistor 110 by storing (e.g., writing) a quantity of electrons (e.g., an amount of charge) on the charge trapping structure 120. An amount of charge to be stored on the charge trapping structure 120 may depend on the logic value to be stored. The charge stored on the charge trapping structure 120 may affect the threshold voltage of the transistor 110, thereby affecting the amount of current that flows through the transistor 110 when the transistor 110 is activated (e.g., when a voltage is applied to the control gate 115, when the memory cell 105-a is read). In some examples, the charge trapping structure 120 may be an example of a floating gate or a replacement gate that may be part of a 2D NAND structure. For example, a 2D NAND array may include multiple control gates 115 and charge trapping structures 120 arranged around a single channel (e.g., a horizontal channel, a vertical channel, a columnar channel, a pillar channel).

A logic value stored in the transistor 110 may be sensed (e.g., as part of a read operation) by applying a voltage to the control gate 115 (e.g., to control node 140, via a word line 165) to activate the transistor 110 and measuring (e.g., detecting, sensing) an amount of current that flows through the first node 130 or the second node 135 (e.g., via a bit line 155). For example, a sense component 170 may determine whether an SLC memory cell 105 stores a logic 0 or a logic 1 in a binary manner (e.g., based on a presence or absence of a current through the memory cell 105 when a read voltage is applied to the control gate 115, based on whether the current is above or below a threshold current). For a multiple-level memory cell 105, a sense component 170 may determine a logic value stored in the memory cell 105 based on various intermediate threshold levels of current when a read voltage is applied to the control gate 115, or by applying different read voltages to the control gate and evaluating different resulting levels of current through the transistor 110, or various combinations thereof. In one example of a multiple-level architecture, a sense component 170 may determine the logic value of a TLC memory cell 105 based on eight different levels of current, or ranges of current, that define the eight potential logic values that could be stored by the TLC memory cell 105.

An SLC memory cell 105 may be written by applying one of two voltages (e.g., a voltage above a threshold or a voltage below a threshold) to the memory cell 105 to store, or not store, an electric charge on the charge trapping structure 120 and thereby cause the memory cell 105 to store one of two possible logic values. For example, when a first voltage is applied to the control node 140 (e.g., via a word line 165) relative to a bulk node 145 (e.g., a body node) for the transistor 110 (e.g., when the control node 140 is at a higher voltage than the bulk), electrons may tunnel into the charge trapping structure 120. Injection of electrons into the charge trapping structure 120 may be referred to as programming the memory cell 105 and may occur as part of a write operation. A programmed memory cell may, in some cases, be considered as storing a logic 0. When a second voltage is applied to the control node 140 (e.g., via the word line 165) relative to the bulk node 145 for the transistor 110 (e.g., when the control node 140 is at a lower voltage than the bulk node 145), electrons may leave the charge trapping structure 120. Removal of electrons from the charge trapping structure 120 may be referred to as erasing the memory cell 105 and may occur as part of an erase operation. An erased memory cell may, in some cases, be considered as storing a logic 1. In some cases, memory cells 105 may be programmed at a page level of granularity due to memory cells 105 of a page sharing a common word line 165, and memory cells 105 may be erased at a block level of granularity due to memory cells 105 of a block sharing commonly biased bulk nodes 145.

In contrast to writing an SLC memory cell 105, writing a multiple-level (e.g., MLC, TLC, or QLC) memory cell 105 may involve applying different voltages to the memory cell 105 (e.g., to the control node 140 or bulk node 145 thereof) at a finer level of granularity to more finely control the amount of charge stored on the charge trapping structure 120, thereby enabling a larger set of logic values to be represented. Thus, multiple-level memory cells 105 may provide greater density of storage relative to SLC memory cells 105 but may, in some cases, involve narrower read or write margins or greater complexities for supporting circuitry.

A charge-trapping NAND memory cell 105 may operate similarly to a floating-gate NAND memory cell 105 but, instead of or in addition to storing a charge on a charge trapping structure 120, a charge-trapping NAND memory cell 105 may store a charge representing a logic state in a dielectric material between the control gate 115 and a channel (e.g., a channel between a first node 130 and a second node 135). Thus, a charge-trapping NAND memory cell 105 may include a charge trapping structure 120, or may implement charge trapping functionality in one or more portions of dielectric material 125, among other configurations.

In some examples, each page of memory cells 105 may be connected to a corresponding word line 165, and each column of memory cells 105 may be connected to a corresponding bit line 155 (e.g., digit line). Thus, one memory cell 105 may be located at the intersection of a word line 165 and a bit line 155. This intersection may be referred to as an address of a memory cell 105. In some cases, word lines 165 and bit lines 155 may be substantially perpendicular to one another, and may be generically referred to as access lines or select lines.

In some cases, a memory device 100 may include a three-dimensional (3D) memory array, where multiple two-dimensional (2D) memory arrays may be formed on top of one another. In some examples, such an arrangement may increase the quantity of memory cells 105 that may be fabricated on a single die or substrate as compared with 1D arrays, which, in turn, may reduce production costs, or increase the performance of the memory array, or both. In the example of FIG. 1, memory device 100 includes multiple levels (e.g., decks, layers, planes, tiers) of memory cells 105. The levels may, in some examples, be separated by an electrically insulating material. Each level may be aligned or positioned so that memory cells 105 may be aligned (e.g., exactly aligned, overlapping, or approximately aligned) with one another across each level, forming a memory cell stack 175. In some cases, memory cells aligned along a memory cell stack 175 may be referred to as a string of memory cells 105.

Accessing memory cells 105 may be controlled through a row decoder 160 and a column decoder 150. For example, the row decoder 160 may receive a row address from the memory controller 180 and activate an appropriate word line 165 based on the received row address. Similarly, the column decoder 150 may receive a column address from the memory controller 180 and activate an appropriate bit line 155. Thus, by activating one word line 165 and one bit line 155, one memory cell 105 may be accessed. As part of such accessing, a memory cell 105 may be read (e.g., sensed) by sense component 170. For example, the sense component 170 may be configured to determine the stored logic value of a memory cell 105 based on a signal generated by accessing the memory cell 105. The signal may include a current, a voltage, or both a current and a voltage on the bit line 155 for the memory cell 105 and may depend on the logic value stored by the memory cell 105. The sense component 170 may include various circuitry (e.g., transistors, amplifiers) configured to detect and amplify a signal (e.g., a current or voltage) on a bit line 155. The logic value of memory cell 105 as detected by the sense component 170 may be output via input/output component 190. In some cases, a sense component 170 may be a part of a column decoder 150 or a row decoder 160, or a sense component 170 may otherwise be connected to or in electronic communication with a column decoder 150 or a row decoder 160.

A memory cell 105 may be programmed or written by activating the relevant word line 165 and bit line 155 to enable a logic value (e.g., representing one or more bits of information) to be stored in the memory cell 105. A column decoder 150 or a row decoder 160 may accept data (e.g., from the input/output component 190) to be written to the memory cells 105. In the case of NAND memory, a memory cell 105 may be written by storing electrons in a charge trapping structure or an insulating layer.

A memory controller 180 may control the operation (e.g., read, write, re-write, refresh) of memory cells 105 through the various components (e.g., row decoder 160, column decoder 150, sense component 170). In some cases, one or more of a row decoder 160, a column decoder 150, and a sense component 170 may be co-located with a memory controller 180. A memory controller 180 may generate row and column address signals in order to activate a desired word line 165 and bit line 155. In some examples, a memory controller 180 may generate and control various voltages or currents used during the operation of memory device 100.

In some manufacturing processes of the memory device 100, a memory cell stack 175 may be formed within a pillar that extends through a stack of alternating oxide and metal layers. The memory device 100 may include a respective set of pillars for each bit line 155, where each pillar is associated with an intersection between the respective bit line 155 and a set of word lines 165. The pillar including the memory cells 105 may be referred to as a memory channel, in some examples. Each memory cell 105 in the pillar may be coupled with a respective word line 165 from among the set of word lines 165 and with the bit line 155. After the pillar is formed, a second cavity may be formed in a stack of materials that is deposited above the pillar, and the second cavity may act as a connecting channel that connects the memory channel to a respective bit line 155. In some examples, however, techniques for depositing the connecting channel may provide for discontinuities between the memory channel and the connecting channel. As such, current may not flow continuously between the memory cells 105 and the bit line 155, which may reduce reliability of the memory device 100.

In some implementations, to improve continuity within the memory device 100, a single conductive material may be deposited, during manufacture of a memory cell stack 175, within a memory channel, a connecting channel, and a junction region between the memory channel and the connecting channel. Thus, the resulting memory device 100 may include a single conductive liner that is continuous across sidewalls of the memory channel, the junction region, and the connecting channel, thereby improving continuity and providing a continuous channel for current flow. The described techniques may thereby provide for improved connections between the memory cells 105 and the bit lines 155, among other connections.

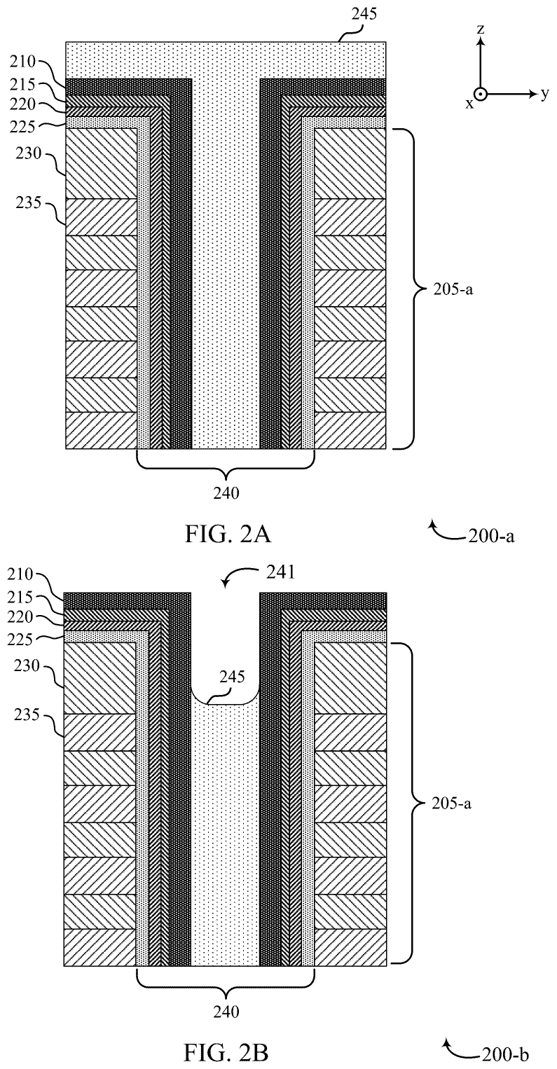

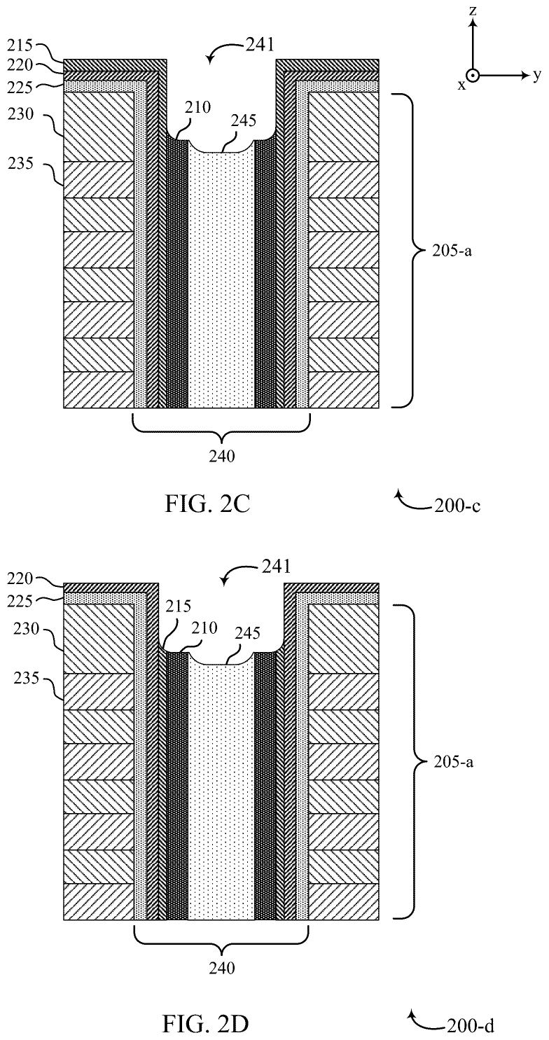

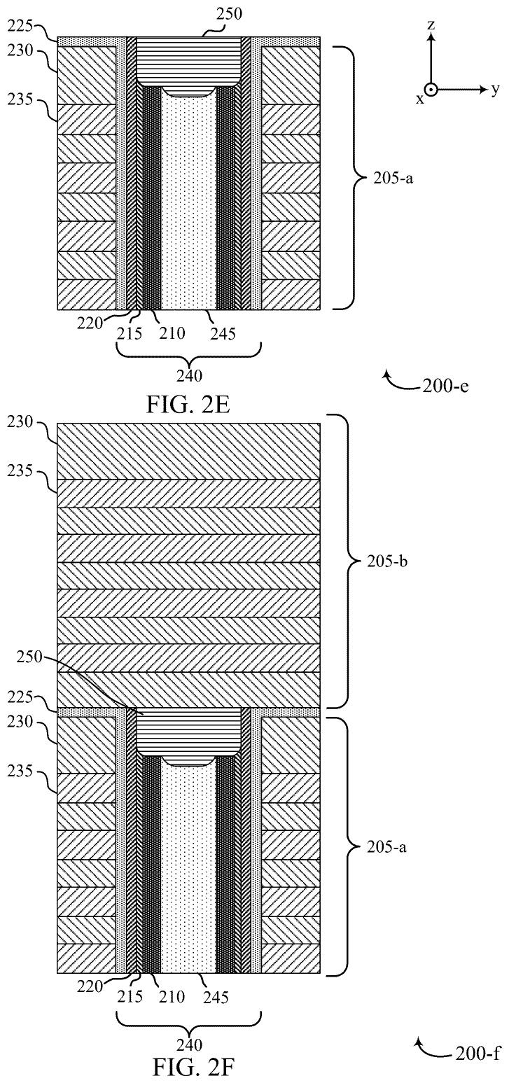

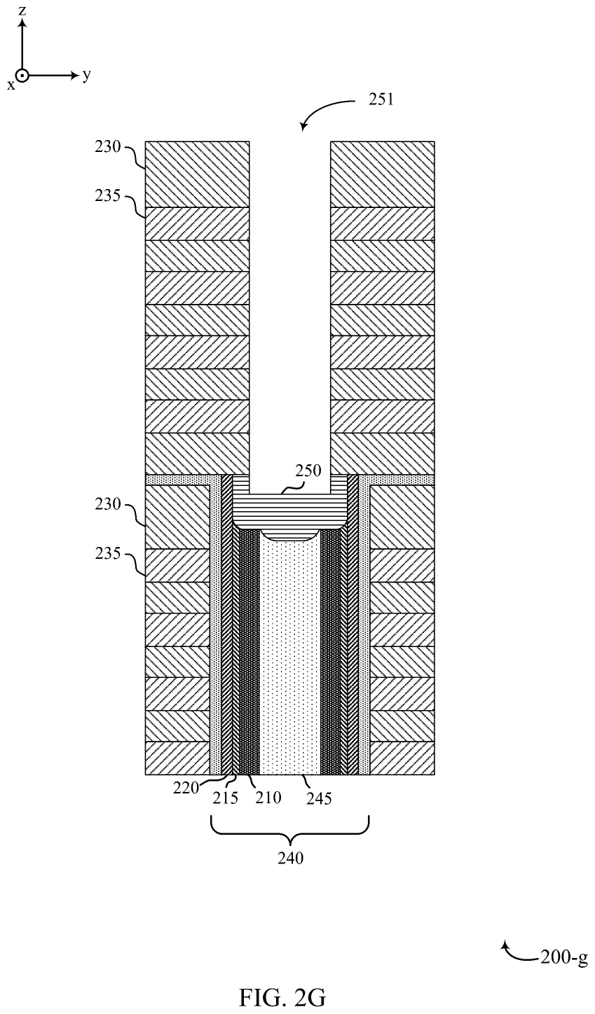

FIGS. 2A through 2G show examples of fabrication operations (e.g.,

manufacturing operations) that support improving continuity in memory arrays in accordance with examples as disclosed herein. For example, FIGS. 2A through 2G may illustrate aspects of sequences of operations for fabricating aspects of a memory array 200, which may be an example of implementing aspects of a memory device 100 as described with reference to FIG. 1, among other types of memory architectures.

Each of FIGS. 2A through 2G may illustrate aspects of manufacturing a portion of a memory array 200 after different subsets of fabrication operations for forming the memory array 200. For example, FIG. 2A may illustrate the memory array 200-a after a first set of fabrication operations, FIG. 2B may illustrate the memory array 200-b after a second set of fabrication operations, and so on. Each view of the figures may be described with reference to an x-direction, a y-direction, and a z-direction, as illustrated. FIGS. 2A through 2G may be a cross sectional view (e.g., viewed according to the z-axis in the vertical direction, the y-axis in the horizontal direction, and the x-axis going into the page) of the memory array 200.

Operations illustrated in and described with reference to FIGS. 2A through 2G may be performed by a manufacturing system, such as a semiconductor fabrication system configured to perform additive operations (e.g., deposition, epitaxy, bonding), subtractive operations (e.g., etching, trenching, planarizing, polishing, exhuming), modifying operations (e.g., oxidizing, doping, reacting, converting), and supporting operations (e.g., masking, patterning, photolithography, aligning), among other operations that support the described techniques. In some examples, operations performed by such a manufacturing system may be supported by a process controller or its components as described herein.

Although aspects of the memory array 200 illustrate examples of relative dimensions and quantities of various features, aspects of the memory array 200 may be implemented with other relative dimensions or quantities of such features in accordance with examples as disclosed herein. In the following description of the memory array 200, some methods, techniques, processes, and operations may be performed in different orders, or at different times, or otherwise modified. Further, some operations for fabricating a memory array 200 (e.g., for fabrication in accordance with an array architecture) may be omitted from the described fabrication operations, or other operations may be added to the described fabrication operations.

FIG. 2A illustrates an example of the memory array (e.g., as a memory array 200-a) after a first set of one or more fabrication operations. For example, the memory array 200-a may include a stack 205-a of material including a set of oxide layers 230 and metal layers 235 formed above a substrate (e.g., semiconductor substrate, a semiconductor wafer). The stack 205-a may include a pillar 240 that extends through the stack 205-a. The pillar 240 may include at least an oxide material 245 and a layer of protective material 210 positioned between the oxide material 245 and sidewalls of the stack 205-a. In some examples, the pillar 240 may additionally, or alternatively, include one or more of an oxide liner 215, a nitride liner 220, and a sacrificial liner 225, each of which may extend along sidewalls and a top portion of the stack 205-a.

In some examples, the set of operations may include forming the stack 205-a over the substrate, which may include alternating layers (e.g., layers along an xy-plane, alternating and having a thickness along the z-direction) of the oxide layers 230 and metal layers 235. The set of operations may also include etching a cavity in the stack 205-a, where the cavity may extend through each of the layers of the stack 205-a to the substrate. In some examples, the cavity may be a via hole or some other hole that extends through the stack. The cavity may provide an opening in which the pillar 240 may be formed. In some examples, the set of operations may further include depositing the sacrificial material in the cavity to form the sacrificial liner 225. The sacrificial liner 225 may extend along the sidewalls of the stack 205-a (e.g., on all sides of the cavity) and may extend along a top surface of the stack 205-a (e.g., a surface furthest from the substrate). The set of operations may include depositing a nitride material on top of the sacrificial material in the cavity to form the nitride liner 220. The set of operations may include depositing an oxide material on top of the nitride liner 220 in the cavity to form the oxide liner 215. The set of operations may include depositing a protective material 210 on top of the oxide liner 215 in the cavity to form the layer of protective material 210. In some examples, the protective material may be a polymer material, or some other type of material.

Each of the sacrificial liner 225, the nitride liner 220, the oxide liner 215, and the layer of protective material 210 may extend along the sidewalls of the stack 205-a (e.g., on all sides of the cavity) and may extend along a top surface of the stack 205-a (e.g., a surface furthest from the substrate). The sacrificial liner 225 may be positioned closest to (e.g., in contact with) the oxide layers 230 and the metal layers 235 in the stack 205-a. The sacrificial liner 225 may be positioned between the nitride liner 220 and the stack 205-a. The nitride liner 220 may be positioned between the oxide liner 215 and the sacrificial liner 225. The oxide liner 215 may be positioned between the layer of protective material 210 and the nitride liner 220. The pillar 240 may thereby include alternating liners that cover the oxide layers 230 and the metal layers 235 in the stack 205-a. In some examples, each material may be etched or otherwise removed or planarized after deposition to form the liners.

The set of operations may further include depositing the oxide material 245 in a remainder of the cavity to form the pillar 240. The oxide material 245 may fill remaining space within the cavity and may be an innermost material within the cavity. The oxide material 245 may, in some examples, be deposited above the top surface of the stack 205-a.

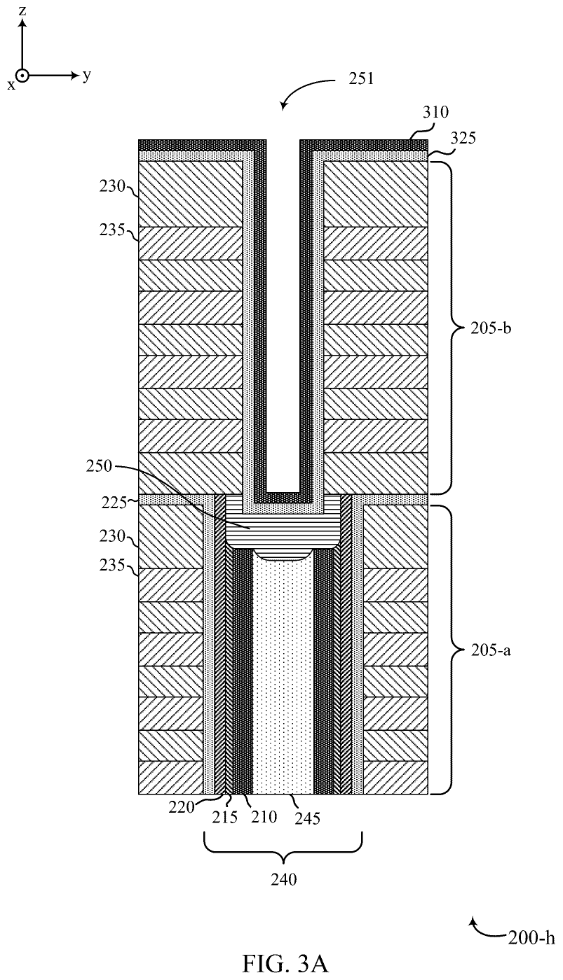

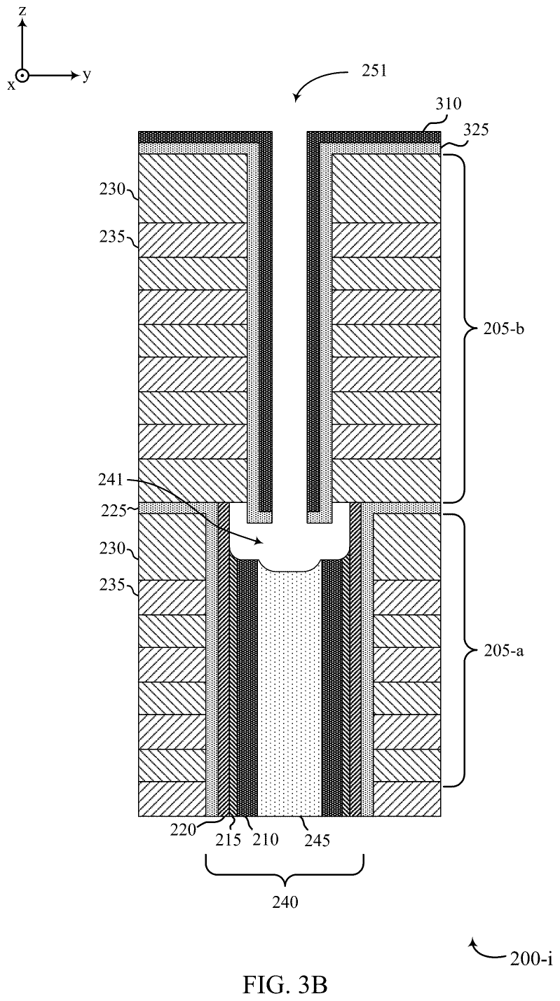

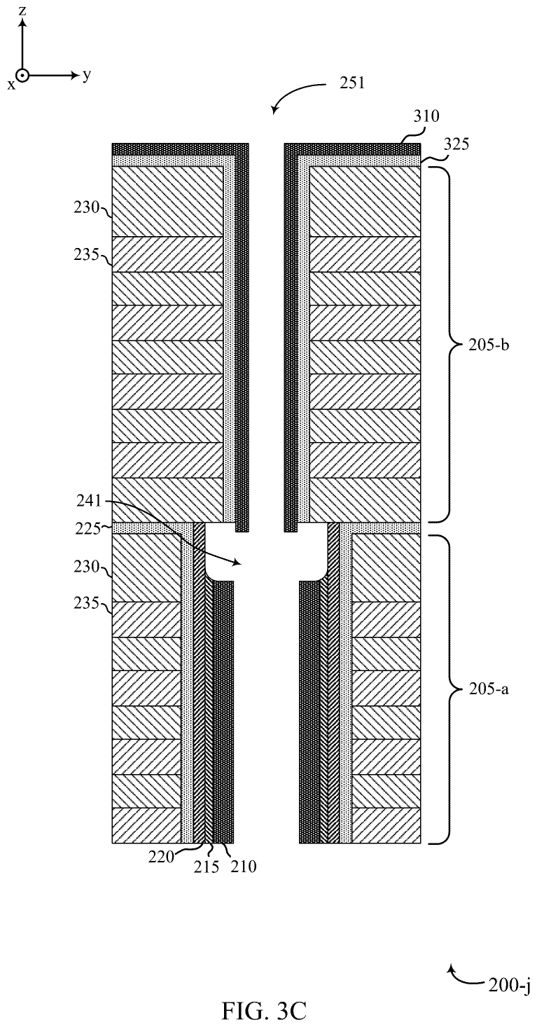

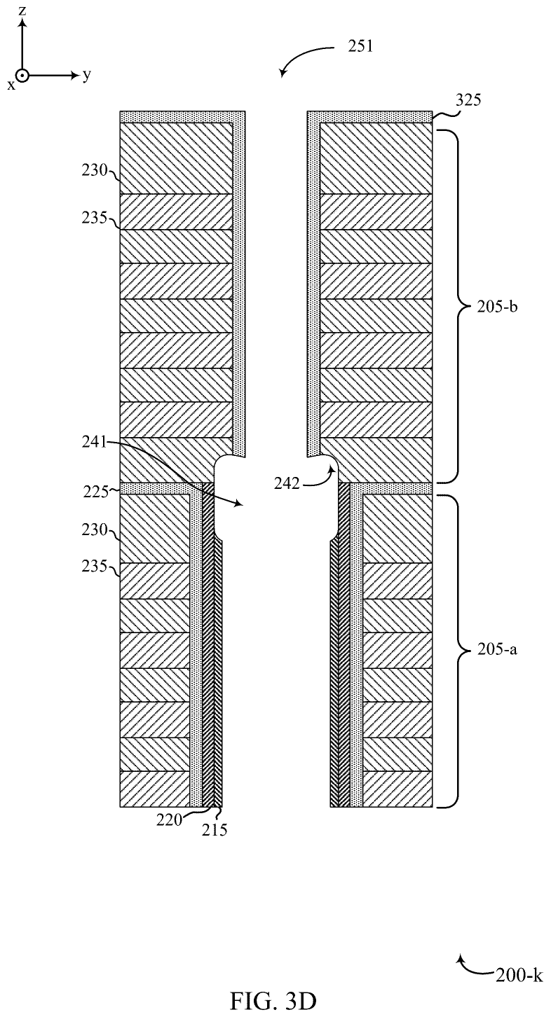

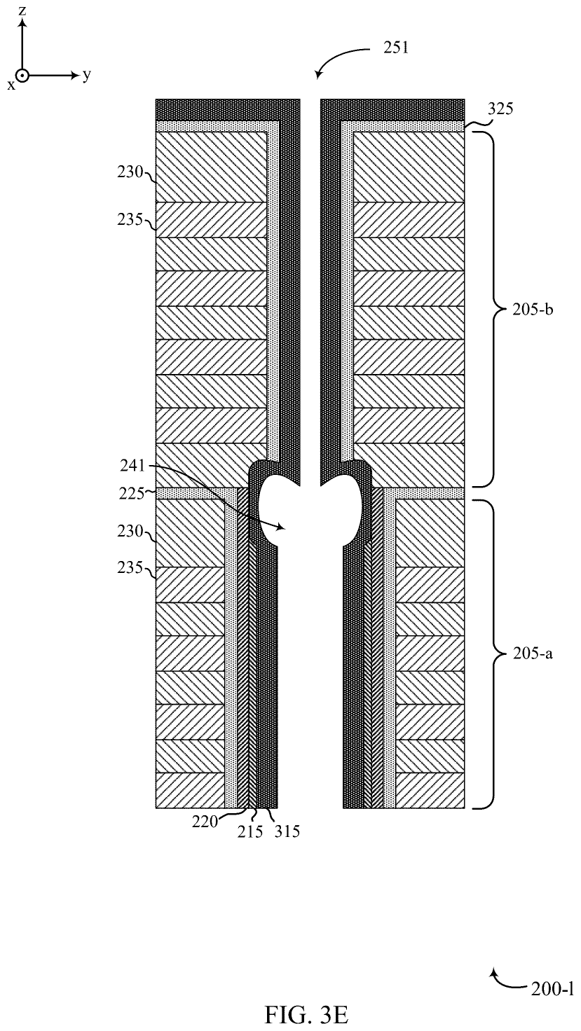

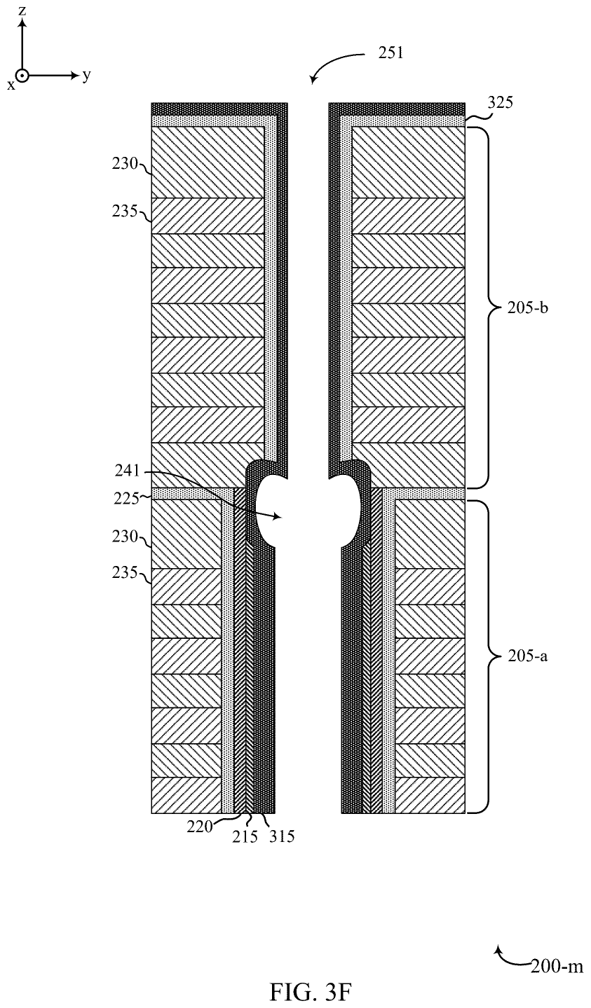

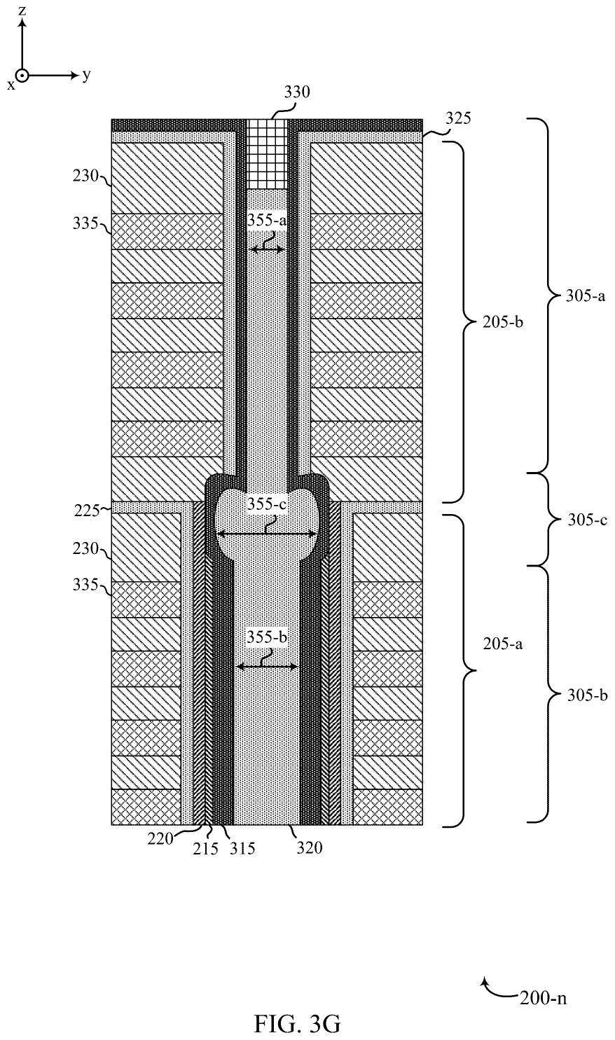

A memory channel may subsequently be formed within the pillar 240. For example, one or more memory cells 105 may be formed (e.g., in subsequent formation operations) at the intersections of the pillar 240 and the metal layers 235. In some examples, a metallization process may be performed as part of formation of the memory cells 105, as described with reference to FIGS. 3G, 4G, and 5D, among other sections.

The set of operations described herein may thereby provide for deposition of each of the sacrificial liner 225, the nitride liner 220, the oxide liner 215, and the layer of protective material 210 along sidewalls and a top surface of the stack 205-a before formation of a connecting channel above the stack 205-a. The various liners, including the layer of protective material 210, formed in this way may provide for reduced processing steps when forming connection between a memory channel and an access line. For example, by depositing at least the nitride liner 220 and the layer of protective material 210 along sidewalls as well as the top surface of the stack 205-a, the nitride and protective materials may remain even with the top surface of the stack 205-a after subsequent formation operations, as described herein, which may improve continuity within the connecting region between the memory channel and a bit line as compared with systems in which the nitride liner 220 and the layer of protective material 210 are not deposited along the top surface of the stack 205-a.

FIG. 2B illustrates an example of the memory array (e.g., as a memory array 200-b) after a second set of one or more fabrication operations. For example, the memory array 200-b may include the stack 205-a of material including the set of oxide layers 230 and metal layers 235 formed above the substrate (e.g., semiconductor substrate, a semiconductor wafer). The stack 205-a may include the pillar 240 that extends through the stack 205-a. The pillar 240 may include the oxide material 245 and the layer of protective material 210 positioned between the oxide material 245 and sidewalls of the stack 205-a. In some examples, the pillar 240 may additionally, or alternatively, include one or more of the oxide liner 215, the nitride liner 220, and the sacrificial liner 225, each of which may extend along sidewalls and a top portion of the stack 205-a, as described with reference to FIG. 2A. After the second set of one or more fabrication operations, a portion of the oxide material 245 may be removed, such that the pillar 240 includes a recess 241.

In some examples, the second set of operations may include an oxide removal process. For example, a portion of the oxide material 245 may be removed via an etch procedure, or some other removal technique (e.g., an oxide exhume or etch). The portion of the oxide material 245 that is removed may include the oxide material 245 deposited above the top surface of the stack 205-a and some oxide material 245 within the pillar 240 (e.g., oxide material 245 at a first layer of the stack 205-a). The removal of the oxide material 245 may form the recess 241, which may be an absence of material within the pillar 240. The remaining oxide material 245 in the pillar 240 may fill a portion of the pillar 240 and may have a curved or straight surface.

FIG. 2C illustrates an example of the memory array (e.g., as a memory array 200-c) after a third set of one or more fabrication operations. For example, the memory array 200-c may include the stack 205-a of material including the set of oxide layers 230 and metal layers 235 formed above the substrate (e.g., semiconductor substrate, a semiconductor wafer). The stack 205-a may include the pillar 240 that extends through the stack 205-a. The pillar 240 may include the oxide material 245 and the layer of protective material 210 positioned between the oxide material 245 and sidewalls of the stack 205-a. In some examples, the pillar 240 may additionally, or alternatively, include one or more of the oxide liner 215, the nitride liner 220, and the sacrificial liner 225, each of which may extend along sidewalls and a top portion of the stack 205-a, as described with reference to FIG. 2A. After the third set of one or more fabrication operations, a portion of the layer of protective material 210 may be removed, such that the recess 241 is expanded within the pillar 240. The layer of protective material 210 may extend along sidewalls of the stack 205-a (e.g., on top of the sacrificial liner 225, the nitride liner 220, and the oxide liner 215) until the layer of protective material 210 is nearly even with the top surface of the oxide material 245 in the pillar 240. In some examples, the oxide material 245 may have a curved top surface, and the top surface of the layer of protective material 210 may similarly be curved.

In some examples, the third set of operations may include a protective material removal process (e.g., a polymer removal process). For example, a portion of the layer of protective material 210 may be removed via an etch procedure, or some other removal technique (e.g., a protective material exhume or etch). The removal technique may remove the layer of protective material 210, but may not remove the oxide material 245 or other materials. As such, the layer of protective material 210 may be removed until a top surface of the layer of protective material 210 along sidewalls of the stack 205-a are nearly parallel or even with a top surface of the oxide material 245. The portion of the layer of protective material 210 that is removed may include the protective material deposited above the top surface of the stack 205-a and some protective material within the pillar 240 (e.g., protective material at a first layer of the stack 205-a). The removal of the layer of protective material 210 may expand a size of the recess 241, which may be an absence of material within the pillar 240.

FIG. 2D illustrates an example of the memory array (e.g., as a memory array 200-d) after a fourth set of one or more fabrication operations. For example, the memory array 200-d may include the stack 205-a of material including the set of oxide layers 230 and metal layers 235 formed above the substrate (e.g., semiconductor substrate, a semiconductor wafer). The stack 205-a may include the pillar 240 that extends through the stack 205-a. The pillar 240 may include the oxide material 245 and the layer of protective material 210 positioned between the oxide material 245 and sidewalls of the stack 205-a. In some examples, the pillar 240 may additionally, or alternatively, include one or more of the oxide liner 215, the nitride liner 220, and the sacrificial liner 225, each of which may extend along sidewalls of the stack 205-a, a top portion of the stack 205-a, or both as described with reference to FIGS. 2A through 2C. After the fourth set of one or more fabrication operations, a portion of the oxide liner 215 may be removed, such that the recess 241 is further expanded within the pillar 240. The remaining oxide liner 215 may extend along sidewalls of the stack 205-a (e.g., on top of the sacrificial liner 225 and the nitride liner 220) until the oxide liner 215 is nearly even with the top surface of the oxide material 245 and the layer of protective material 210 in the pillar 240. In some examples, the oxide material 245 and the top surface of the layer of protective material 210 may have curved surfaces, and the top surface of the oxide liner 215 may similarly be curved.

In some examples, the fourth set of operations may include another oxide removal process (e.g., an oxide removal). For example, a portion of the oxide liner 215 may be removed via an etch procedure, or some other removal technique (e.g., an oxide exhume or etch). The removal technique may remove the oxide liner 215, but may not remove the oxide material 245, the layer of protective material 210, or other materials. As such, the oxide liner 215 may be removed until a top surface of the oxide liner 215 along sidewalls of the stack 205-a is nearly parallel or even with a top surface of the layer of protective material 210 and/or the oxide material 245. The portion of the oxide liner 2 that is removed may include the oxide material deposited above the top surface of the stack 205-a and some oxide material within the pillar 240 (e.g., oxide material at a first layer of the stack 205-a). The removal of the oxide liner 215 may further expand a size of the recess 241, which may be an absence of material within the pillar 240. In some examples, the portion of the oxide liner 215 may not be removed, and the recess 241 may remain the same size as illustrated in FIG. 2C.

FIG. 2E illustrates an example of the memory array (e.g., as a memory array 200-e) after a fifth set of one or more fabrication operations. For example, the memory array 200-e may include the stack 205-a of material including the set of oxide layers 230 and metal layers 235 formed above the substrate (e.g., semiconductor substrate, a semiconductor wafer). The stack 205-a may include the pillar 240 that extends through the stack 205-a. The pillar 240 may include the oxide material 245 and the layer of protective material 210 positioned between the oxide material 245 and sidewalls of the stack 205-a. In some examples, the pillar 240 may additionally, or alternatively, include one or more of the oxide liner 215, the nitride liner 220, and the sacrificial liner 225, each of which may extend along sidewalls of the stack 205-a. The sacrificial liner 225 may additionally extend along a top portion of the stack 205-a, as described with reference to FIG. 2A. After the fifth set of one or more fabrication operations, a portion of the nitride liner 220 may be removed, such that the nitride liner 220 no longer extends along the top surface of the stack 205-a. Instead, the nitride liner 220 may extend along sidewalls of the stack 205-a and a top surface of the nitride liner may be parallel with or nearly even with a top surface of the sacrificial liner 225 that extends along the top surface of the stack 205-a.

Additionally, after the fifth set of one or more fabrication operations, the recess 241 may be filled with a sacrificial material 250 (e.g., a silicon nitride material, or some other type of sacrificial material). The pillar 240 may thereby include the oxide material 245, the layer of protective material 210, the oxide liner 215, the nitride liner 220, and the sacrificial liner 225, as well as the sacrificial material 250 filled above the other materials and liners.

In some examples, the fifth set of operations may include a nitride material removal process. For example, a portion of the nitride liner 220 may be removed via an etch procedure. The removal technique may remove the nitride liner 220, but may not remove the other materials in the stack 205-a. As such, the nitride liner 220 may be removed until a top surface of the nitride liner 220 along sidewalls of the stack 205-a is nearly parallel or even with a top surface of the sacrificial liner 225 extending along the top surface of the stack 205-a. The portion of the nitride liner 220 that is removed may include the nitride material deposited above the top surface of the stack 205-a and some protective material within the pillar 240 (e.g., protective material at a first layer of the stack 205-a).

In some examples, the fifth set of operations may further include a sacrificial material 250 deposition. For example, the sacrificial material 250 may be deposited within the recess 241. In some examples, a top portion of the sacrificial material 250 may be planarized such that the sacrificial material is even with a top surface of the sacrificial liner 225. The sacrificial material 250 may be, for example, a silicon nitride material, and aluminum oxide material, or some other type of material. In some examples, the deposition may include a silicon nitride chemical mechanical polishing (CMP) deposition or an aluminum oxide fill.

FIG. 2F illustrates an example of the memory array (e.g., as a memory array 200-f) after a sixth set of one or more fabrication operations. For example, the memory array 200-f may include the stack 205-a of material including the set of oxide layers 230 and metal layers 235 formed above the substrate (e.g., semiconductor substrate, a semiconductor wafer). The stack 205-a may include the pillar 240 that extends through the stack 205-a. The pillar 240 may include the oxide material 245 and the layer of protective material 210 positioned between the oxide material 245 and sidewalls of the stack 205-a. The pillar 240 may additionally include the oxide liner 215, the nitride liner 220, and the sacrificial liner 225, each of which may extend along sidewalls of the stack 205-a. The sacrificial liner 225 may further extend along a top portion of the stack 205-a, as described with reference to FIG. 2A. The pillar 240 may further include the sacrificial material 250 positioned above the oxide material, the layer of protective material 210, and the oxide liner.

After the sixth set of one or more fabrication operations, the memory array 200-f may further include a second stack 205-b of material positioned above the first stack 205-a relative to the substrate. The second stack 205-b may include a second set of oxide layers 230 and metal layers 235 formed in an alternating fashion above the first stack 205-a. A first layer of the second stack 205-b may be formed over the top surface of the sacrificial liner 225, a top surface of the nitride liner 220, and a top surface of the sacrificial material 250, which may form a relatively even surface based on the first through fifth sets of fabrication operations as described herein.

In some examples, the sixth set of operations may include a forming the second stack 205-b over the first stack 205-a, which may include alternating layers (e.g., layers along an xy-plane, alternating and having a thickness along the z-direction) of the oxide layers 230 and metal layers 235.

FIG. 2G illustrates an example of the memory array (e.g., as a memory array 200-g) after a seventh set of one or more fabrication operations. For example, the memory array 200-g may include the stack 205-a of material including the set of oxide layers 230 and metal layers 235 formed above the substrate (e.g., semiconductor substrate, a semiconductor wafer). The stack 205-a may include the pillar 240 that extends through the stack 205-a. The pillar 240 may include the oxide material 245 and the layer of protective material 210 positioned between the oxide material 245 and sidewalls of the stack 205-a. The pillar 240 may additionally include the oxide liner 215, the nitride liner 220, and the sacrificial liner 225, each of which may extend along sidewalls of the stack 205-a. The sacrificial liner 225 may further extend along a top portion of the stack 205-a, as described with reference to FIG. 2A. The pillar 240 may further include the sacrificial material 250 positioned above the oxide material, the layer of protective material 210, and the oxide liner. The memory array 200-g may further include the second stack 205-b of material including alternating oxide layers 230 and metal layers 235 formed above the stack 205-a.

After the seventh set of one or more fabrication operations, the memory array 200-g may further include a cavity 251 that extends through the second stack 205-b. The cavity 251 may extend through the second stack 205-b of alternating oxide layers 230 and metal layers 235 and may further extend into a portion of the sacrificial material 250, in some examples. The cavity 251 may be a recess, hole, via, or other absence of material within a center portion of the stack 205-b.

In some examples, the seventh set of operations may include an etch process (e.g., a select gate drain etch). For example, the stack 205-b of oxide layers 230 and metal layers 235 may be etched to remove material within the cavity 251. The etch may further remove a portion of the sacrificial material 250, in some examples.

After the seventh set of one or more fabrication operations, the memory array 200-g may be ready for generation of a connecting channel and one or more metallization processes to transform the pillar 240 to a memory channel (e.g., including memory cells 105 at an intersection of the pillar 240 and the metal layers 235). In some systems, a connection between a memory channel and a connecting channel may be associated with relatively high resistance. For example, some techniques for memory formation may include deposition of a conductive liner within the first stack 205-a before forming the second stack 205-b, and may form a second conductive liner that contacts the first conductive liner, which may result in connectivity issues due to unreliable contact points between the liners, among other examples.

The techniques described herein provide for an improved memory channel connection via a refined manufacturing process. For example, the deposition of the materials and formation of the cavity 251 as described herein may provide for subsequent deposition of a continuous conductive channel through the first stack 205-a, the second stack 205-b, and a connection region between the stacks 205. For example, by depositing the nitride liner 220 along the sidewalls and the top surface of the stack 205-a, the nitride liner 220 may be planarized (e.g., removed) from the top surface of the stack and a top surface of the nitride liner 220 may be even with (e.g., parallel to) a top surface of the stack 205-a, such that a first layer of the second stack 205-b may be in contact with the top surface of the nitride liner 220. Such a formation technique may provide for improved continuity of a connecting or junction region subsequently formed between the first stack 205-a and the second stack 205-b by, for example, reducing gaps or holes of material within the junction region.

Additionally, or alternatively, the deposition of the layer of protective material 210 may protect the other liners and materials in the stack during subsequent material removal processes, such as a removal of the oxide material 245, which may provide for deposition of a single conductive liner through both stacks 205-a and 205-b. The single conductive liner may, by nature, not include contact points, which may improve connectivity and may reduce resistance, among other examples, relative to memory arrays in which two conductive liners are coupled.

The generation of the connecting channel may be performed in one or more different ways, as described in further detail elsewhere herein, including with reference to FIGS. 3A through 3G, FIGS. 4A through 4G, and FIGS. 5A through 5D.

FIGS. 3A through 3G show examples of fabrication operations (e.g., manufacturing operations) that support improving continuity in memory arrays in accordance with examples as disclosed herein. For example, FIGS. 3A through 3G may illustrate aspects of sequences of operations for fabricating aspects of a memory array 200, which may be an example of implementing aspects of a memory device 100 as described with reference to FIG. 1, among other types of memory architectures.

Each of FIGS. 3A through 3G may illustrate aspects of a portion of a memory array 200 after different subsets of fabrication operations for forming the memory array 200. For example, FIG. 3A may illustrate the memory array 200-h after a first set of fabrication operations, FIG. 3B may illustrate the memory array 200-i after a second set of fabrication operations, and so on. Each view of the figures may be described with reference to an x-direction, a y-direction, and a z-direction, as illustrated. FIGS. 3A through 3G may be a cross sectional view (e.g., viewed according to the z-axis in the vertical direction, the y-axis in the horizontal direction, and the x-axis going into the page) of the memory array 200.

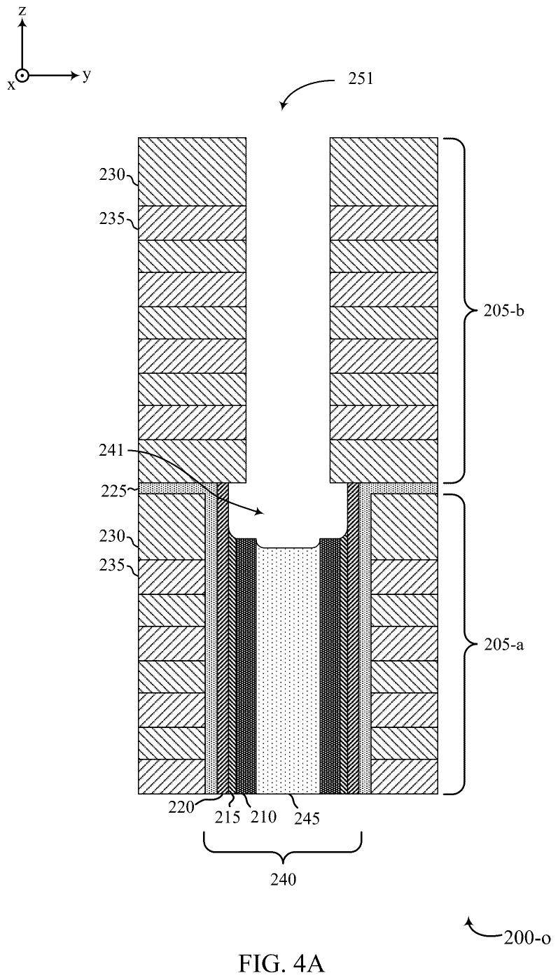

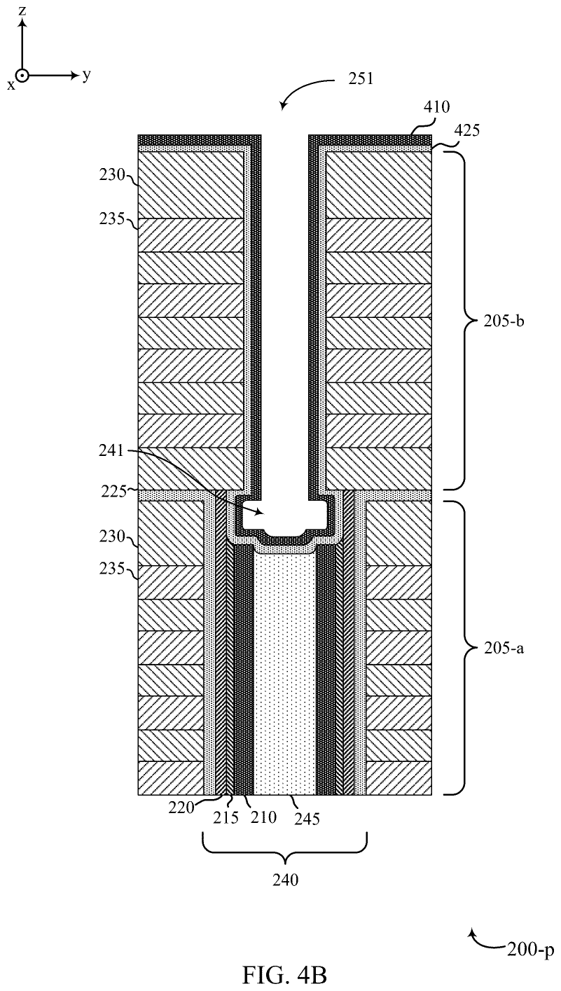

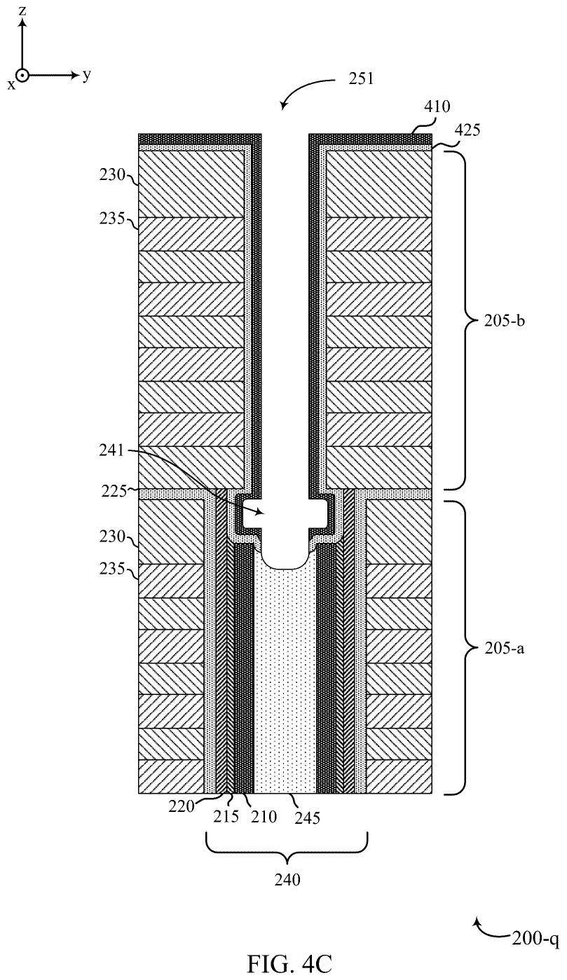

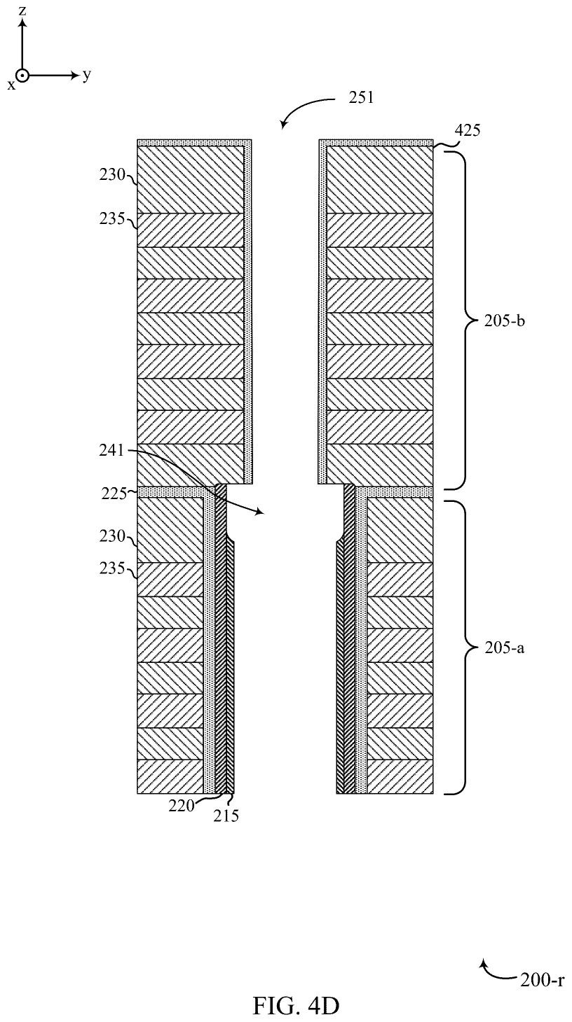

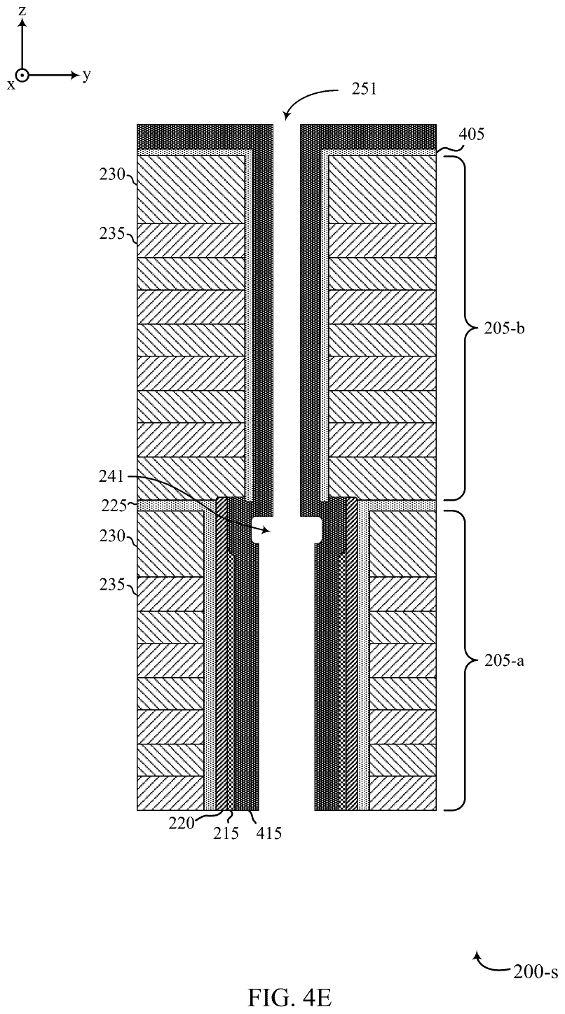

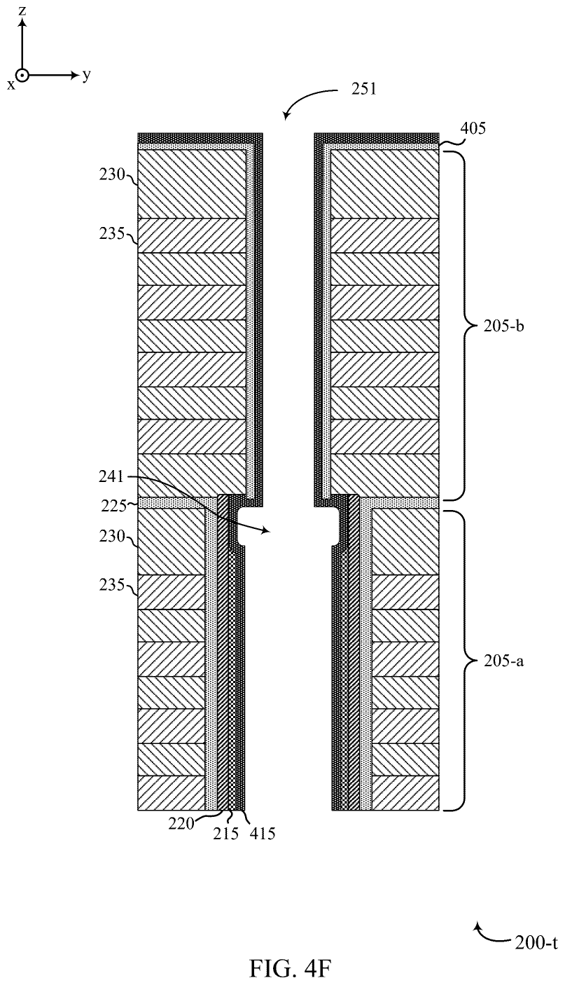

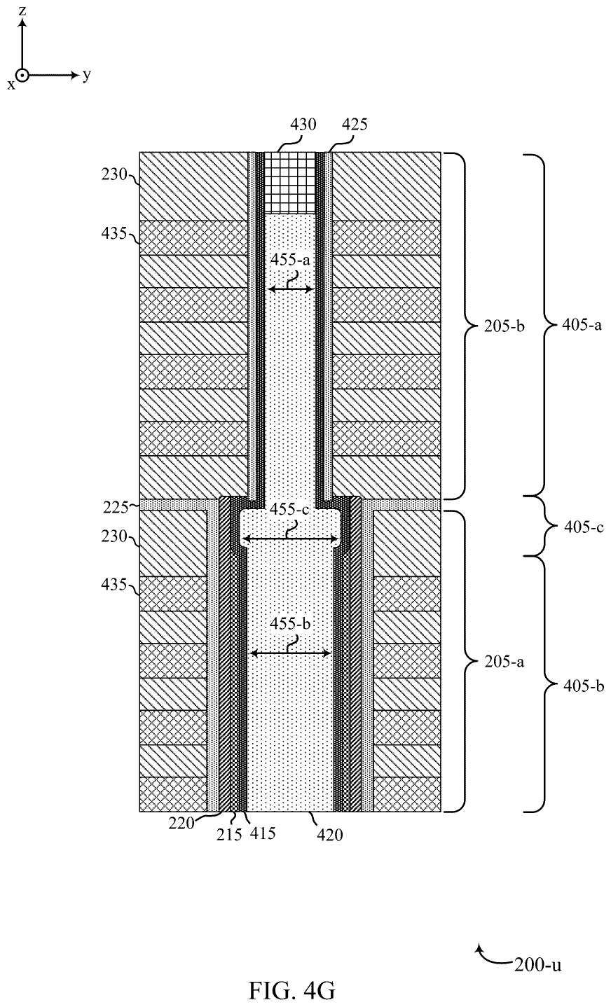

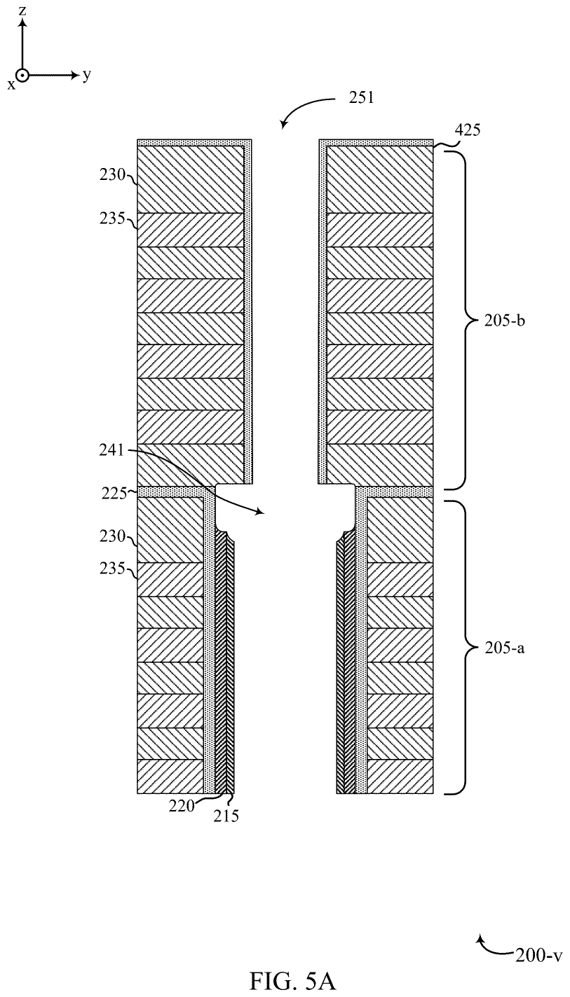

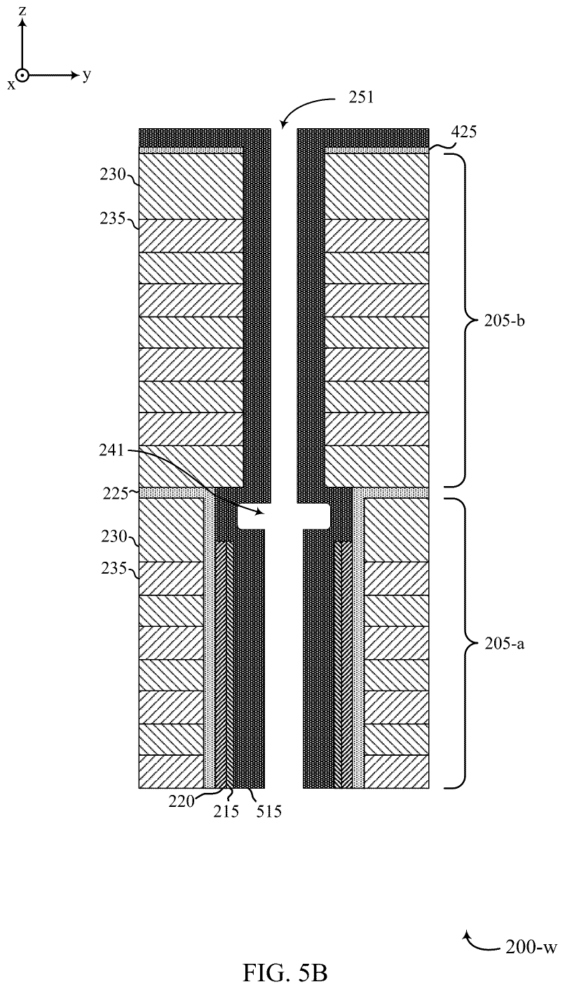

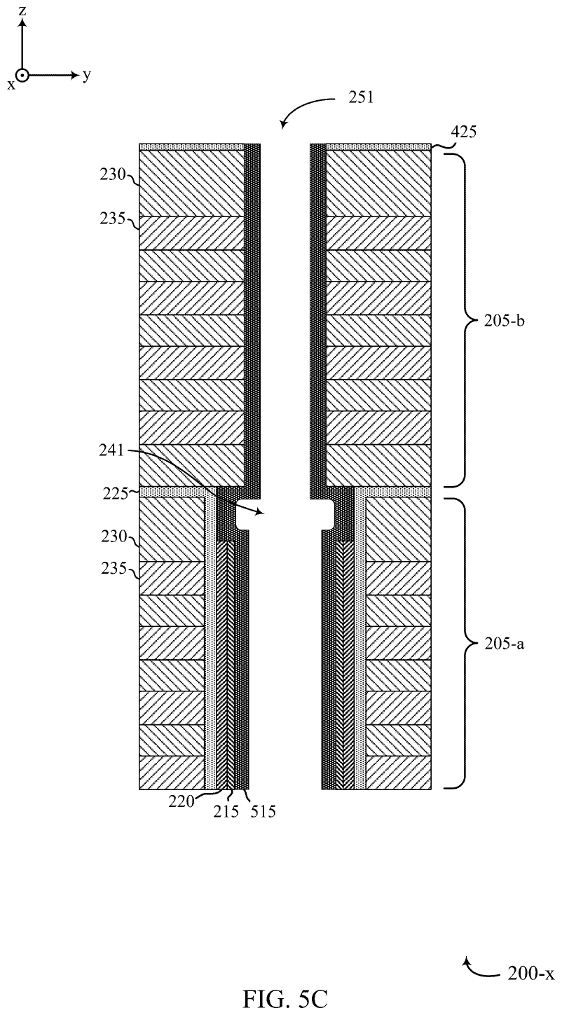

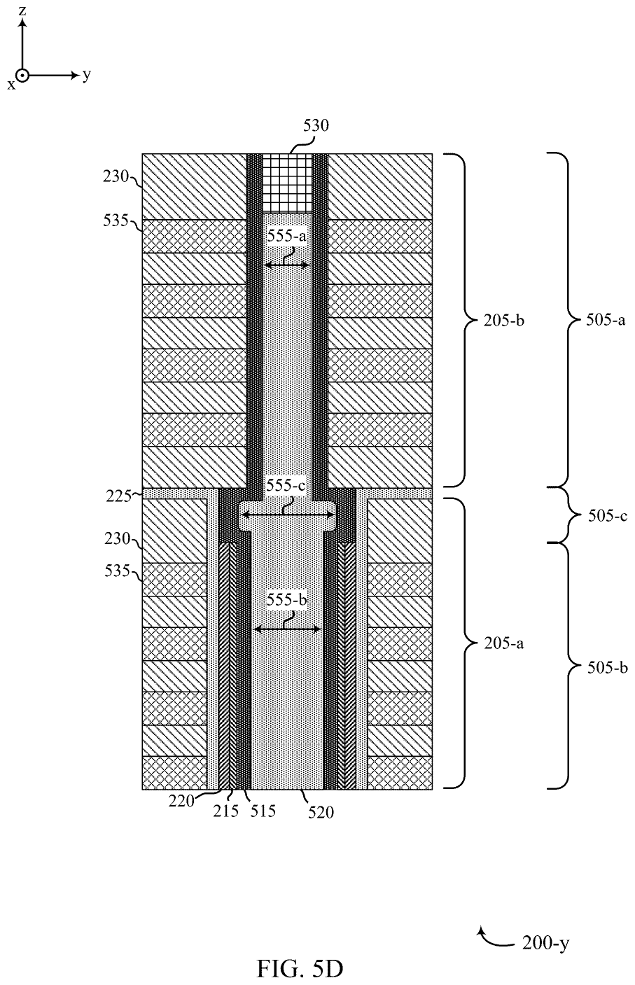

The fabrication operations described with reference to FIGS. 3A through 3G may be performed after the operations described with reference to FIG. 2G. For example, after the memory array 200-g is formed, as described with referenced to FIG. 2G, the memory array 200-g may undergo another set of fabrication operations to generate a conductive connecting memory channel, as described with reference to FIGS. 3A through 3G. In some examples, FIGS. 3A through 3G may represent a first example process for generating a conductive connecting memory channel, but other alternative processes may be supported. For example, FIGS. 4A through 4G as well as FIGS. 5A through 5D may illustrate other processes for generating a conductive memory channel as described herein.

Operations illustrated in and described with reference to FIGS. 3A through 3G may be performed by a manufacturing system, such as a semiconductor fabrication system configured to perform additive operations (e.g., deposition, epitaxy, bonding), subtractive operations (e.g., etching, trenching, planarizing, polishing, exhuming), modifying operations (e.g., oxidizing, doping, reacting, converting), and supporting operations (e.g., masking, patterning, photolithography, aligning), among other operations that support the described techniques. In some examples, operations performed by such a manufacturing system may be supported by a process controller or its components as described herein.

Although aspects of the memory array 200 illustrate examples of relative dimensions and quantities of various features, aspects of the memory array 200 may be implemented with other relative dimensions or quantities of such features in accordance with examples as disclosed herein. In the following description of the memory array 200, some methods, techniques, processes, and operations may be performed in different orders, or at different times, or otherwise modified. Further, some operations for fabricating a memory array 200 (e.g., for fabrication in accordance with an array architecture) may be omitted from the described fabrication operations, or other operations may be added to the described fabrication operations.

FIG. 3A illustrates an example of the memory array (e.g., as a memory array 200-h) after a first set of one or more fabrication operations. For example, the memory array 200-h may include a stack 205-a of material including a set of oxide layers 230 and metal layers 235 formed above a substrate (e.g., semiconductor substrate, a semiconductor wafer).

The stack 205-a may include the pillar 240 that extends through the stack 205-a. The pillar 240 may include the oxide material 245 and the layer of protective material 210 positioned between the oxide material 245 and sidewalls of the stack 205-a. The pillar 240 may additionally include the oxide liner 215, the nitride liner 220, and the sacrificial liner 225, each of which may extend along sidewalls of the stack 205-a. The sacrificial liner 225 may further extend along a top portion of the stack 205-a, as described with reference to FIG. 2A. The pillar 240 may further include the sacrificial material 250 positioned above the oxide material, the layer of protective material 210, and the oxide liner. The memory array 200-h may further include the second stack 205-b of material including alternating oxide layers 230 and metal layers 235 formed above the stack 205-a. The second stack 205-b may include a cavity 251 that extends through the second stack 205-b. The cavity 251 may extend through the second stack 205-b of alternating oxide layers 230 and metal layers 235 and may further extend into a portion of the sacrificial material 250, in some examples. The cavity 251 may be a recess, hole, via, or other absence of material within a center portion of the stack 205-b.

After the set of one or more fabrication operations described herein, the memory array 200-h may include an oxide liner 325 that extends along sidewalls of the stack 205-b within the cavity 251. For example, the oxide liner 325 may include a layer of oxide material that may be deposited along a bottom surface of the cavity 251 (e.g., on top of the sacrificial material 250), along sidewalls of the stack 205-b within the cavity 251, and along a top surface of the stack 205-b. The memory array 200-h may further include another layer of protective material 310 that extends along the sidewalls of the stack 205-b within the cavity 251 and the top surface of the stack 205-b. For example, the layer of protective material 310 may include a layer of protective material that may be deposited on top of the oxide liner 325. The oxide liner 325 may thereby extend between the layer of protective material 310 and the second stack 205-b.

In some examples, the set of operations may include depositing an oxide material in the cavity 251 to form the oxide liner 325. The set of operations may include depositing a protective material on top of the oxide liner 325 in the cavity 251 to form the layer of protective material 310. In some examples, one or more planarization techniques may be performed to provide for relatively even thickness of the oxide liner 325 and the layer of protective material 310 within the cavity 251 and on top of the stack 205-b.

FIG. 3B illustrates an example of the memory array (e.g., as a memory array 200-i) after a second set of one or more fabrication operations. After the second set of one or more fabrication operations described herein, the memory array 200-i may include the recess 241, which may be an absence of material formed in a junction or connecting region between the stack 205-a and the stack 205-b. The cavity 251 may extend into the recess 241, in some examples. The recess 241 may, in some examples, include a curved bottom surface above the oxide material 245, the layer of protective material 210, and the oxide liner 215 in the pillar 240. The sidewalls of the recess 241 may include top surfaces of the oxide material 245, the layer of protective material 210, and the oxide liner 215 in the pillar 240, as well as a sidewall of the nitride liner 220, a portion of a bottom surface of a first layer in the stack 205-b, and a portion of the oxide liner 325 deposited in the cavity 251.

In some examples, the second set of operations may include an etch and exhume process. For example, the layer of protective material 310 and the oxide liner 325 may be subject to a punch etch, which may etch a bottom portion of each of the liners. The portion of the liners that is removed via the punch etch may have a width that is the same as a width of the cavity 251 after the liners are deposited. Accordingly, the cavity 251, after the punch etch, may be a column that is absent of material. The punch etch may remove the portions of the layer of protective material 310 and the oxide liner 325, but remaining portions of the layer of protective material 310 and the oxide liner 325 may extend along sidewalls of the stack 205-b and a top portion of the stack 205-b after the punch etch.

The second set of operations may further include, in some examples, a sacrificial material exhume process (e.g., an aluminum oxide exhume or a silicon nitride exhume, among other examples). For example, the sacrificial material 250 may be removed from the recess 241 via the exhume process.

FIG. 3C illustrates an example of the memory array (e.g., as a memory array 200-j) after a third set of one or more fabrication operations. After the third set of one or more fabrication operations described herein, the memory array 200-jmay no longer include the oxide material 245 in the pillar 240 within the first stack 205-a.

In some examples, the third set of operations may include an exhume process. For example, the oxide material 245 may be removed, via the cavity 251, from the pillar 240 and the recess 241. The exhume process may remove any exposed oxide materials in the material formation. The layer of protective material 210 may protect the oxide liner 215 from being removed as part of the exhume process. Similarly, the layer of protective material 310 may protect the oxide liner 325 from being removed as part of the exhume process. However, a portion of the oxide liner 325 may be exposed in the recess 241. For example, a portion of the oxide liner 325 that extends below the layer of protective material 310 in the recess 241 (e.g., oxide fangs) may be exposed prior to the exhume and may thereby be removed during the exhume process, which may further increase a size of the recess 241.

In some examples, after removal of the oxide material 245, the cavity 251 may expand. For example, the cavity 251, which may also be referred to as a pillar in some examples herein, may extend from the top surface of the stack 205-b to a bottom surface of the stack 205-a (e.g., through or including the recess 241).

FIG. 3D illustrates an example of the memory array (e.g., as a memory array 200-k) after a fourth set of one or more fabrication operations. After the fourth set of one or more fabrication operations described herein, the layer of protective material 310 and the layer of protective material 210 may be removed from the memory array 200-k.

In some examples, the fourth set of operations may include a removal process. For example, the protective material may be removed, via the cavity 251, from the recess 241 and the cavity 251. The removal process may be an exhume process, and etch process, or some other technique for removing any exposed protective material (e.g., polymer or some other type of material). The removal process may remove a portion of the layer of protective material 310 that extends into the recess 241, as well as a portion of the layer of protective material 310 that is positioned above the recess 241 (e.g., in a first layer of the second stack 205-b). The removal process may not remove other materials from the memory array 200-k. For example, the oxide liner 325 may remain along the sidewalls of the stack 205-b within the cavity 251 and along a top surface of the stack 205-b.

In some examples, as part of the removal of the layer of protective material 310, or as part of the oxide exhume performed previously, a cavity 242 may be formed on each side of the recess 241 in the first oxide layer 230 of the stack 205-b. For example, a portion of material in the first oxide layer 230 may be removed, creating curved corners within the recess 241.

FIG. 3E illustrates an example of the memory array (e.g., as a memory array 200-l) after a fifth set of one or more fabrication operations. After the fifth set of one or more fabrication operations described herein, the memory array 200-l may additionally include a conductive liner 315 that extends along sidewalls of the stack 205-b, the stack 205-a, and the recess 241. For example, the conductive liner 315 may include a conductive material (e.g., polymer, or some other type of material) that is deposited along a top surface of the stack 205-b (e.g., above the oxide liner 325), along sidewalls of the stack 205-b and the stack 205-a within the cavity 251 (e.g., on top of the oxide liner 325) and along sidewalls of the recess 241.

In some examples, the fifth set of operations may include a deposition process (e.g., a polymer deposition reflow). For example, the conductive material may be deposited within the cavity 251 and the recess 241. The conductive material may contact the oxide liner 325 on top of the stack 205-b and along the sidewalls of the stack 205-b within the cavity 251. The conductive material may further contact, after deposition, the first layer (e.g., an oxide layer 230) in the second stack 205-b, the nitride liner 220 in a top portion of the stack 205-a, and then the oxide liner 215 along remaining sidewalls of the stack 205-a within the cavity 251.

In some examples, the conductive liner 315 may include a first segment that extends along the sidewall of the stack 205-a (e.g., a first level). The first segment may be relatively straight. In some examples, the first segment may extend along the sidewall of the stack 205-a on each side of the cavity 251. The conductive liner 315 may further include a second segment that extends along the sidewall of the stack 205-b (e.g., a second level). The second segment may be relatively straight. The second segment may additionally extend along a top surface of the stack 205-b. The conductive liner 315 may further include a third segment that curves along the sidewalks in the recess 241 (e.g., a third level, a connecting or junction region). For example, the conductive liner 315 may curve under the oxide liner 325, along the curved surface of the first oxide layer 230 in the second stack 205-b, along a portion of the oxide liner 215 in the recess 241, along a top surface of the nitride liner 220 in the recess, and then may connect to the first segment that extends along the sidewall of the stack 205-a. The recess 241 may thereby have a curved shape after the deposition of the conductive liner 315.

FIG. 3F illustrates an example of the memory array (e.g., as a memory array 200-m) after a sixth set of one or more fabrication operations. After the sixth set of one or more fabrication operations described herein, the conductive liner 315 of the memory array 200-m may have a second thickness that may be less than a first thickness of the conductive liner 315 before the sixth set of one or more fabrication operations.

In some examples, the sixth set of operations may include an etch or cut process, such as a ULC wet cut. For example, the conductive liner 315 may be cut or refined to reduce the thickness. In some examples, the thickness may be constant or within a threshold thickness range across all of the conductive liner 315. Additionally, or alternatively, the thickness of the conductive liner 315 in the recess 241, for example, may be different than the thickness of the conductive liner 315 in the first stack 205-a.

FIG. 3G illustrates an example of the memory array (e.g., as a memory array 200-n) after a seventh set of one or more fabrication operations. For example, the memory array 200-n may include a stack 205-a of material including a set of oxide layers 230 and metal layers 235 formed above a substrate (e.g., semiconductor substrate, a semiconductor wafer). The stack 205-a may include a pillar that extends through the stack 205-a. The pillar may include the oxide liner 215, the nitride liner 220, and the sacrificial liner 225, each of which may extend along sidewalls of the stack 205-a. The sacrificial liner 225 may further extend along a top portion of the stack 205-a, as described with reference to FIG. 2A. The memory array 200-n may further include the second stack 205-b of material including alternating oxide layers 230 and metal layers 235 formed above the stack 205-a. The second stack 205-b may include a cavity that extends through the second stack 205-b and is filled with an oxide liner 325 that extends along sidewalls of the stack 205-b and a top surface of the stack 205-b.

In some examples, the memory array 200-n may represent a stack of materials, and the stack of materials may include three levels 305, including a first level 305-a, a second level 305-b, and a third level 305-c. In some examples, the third level 305-c of the stack may include a junction region that connects the first level 305-a and the second level 305-b. The first level 305-a may include the first segment of the conductive liner 315 that extends along sidewalls of the stack 205-b, as described with reference to FIG. 3E. The second level 305-b may include the second segment of the conductive liner 315 that extends along sidewalls of the stack 205-a, as described with reference to FIG. 3E. The third level 305-c may include the third segment of the conductive liner 315 that curves along the sidewalls of the recess, as described with reference to FIG. 3E. The third segment of the conductive liner 315 may be coupled with a first oxide layer 230 of the stack 205-b, the oxide liner 325, the nitride liner 220, and a portion of the oxide liner 215.

After the seventh set of one or more fabrication operations, the memory array 200-n may include an oxide material 320 that extends through the second level 305-b, the third level 305-c, and a portion of the first level 305-a. The memory array 200-n may further include a conductive material 330 positioned above the oxide material in the first level 305-a. The conductive material 330, the oxide material 320, and the conductive liner 315 may form a pillar that extends through the levels of the stack, in some examples. In some examples, the pillar may include a first width 355-a in the first level 305-a of the stack, a second width 355-b in the second level 305-b of the stack, and one or more third widths 355-c in the third level 305-c of the stack. For example, because the third level 305-c includes the curved sidewalls, it is to be understood that the pillar (e.g., including the oxide material 320) in the third level 305-c may include varying widths.

The seventh set of one or more fabrication operations described herein may include a metallization (e.g., replacement gate) operation, in some examples. During the metallization procedure, the metal layers 235 (e.g., nitride layers) may be removed to form a set of cavities. Subsequently, a metal may be deposited into the cavities to form second metal layers 335 (e.g., word lines 165). The oxide material 320 may then be deposited in the cavity to form the conductive pillar including the conductive liner 315 and the oxide material 320. The second metal layers 335 may be configured to couple the conductive pillar with supporting circuitry (e.g., word line drivers, among other circuitry). Memory cells 105 may be formed at an intersection of the conductive pillar and the second metal layers 335. The conductive material 330 deposited at the top of the conductive pillar may be configured to couple the conductive pillar with other supporting circuitry or access lines (e.g., a bit line).

The described techniques may thereby provide for formation of a continuous conductive channel or pillar that extends through two separate stacks of memory material and a junction region. The conductive channel may include two relatively straight segments connective by a rounded or curved region. The rounded region may have multiple different widths 355-c, as described herein, due to the curved nature of the region. In some examples, a thickness of the conductive liner 315 may vary within the rounded connecting region. For example, the conductive liner 315 may be relatively thick in the upper corners of the region (e.g., where the cavities 242 were previously located), and may be relatively thinner along the nitride liner 220. The enhanced thickness in the corner and curved portions may provide for improved conductivity and reduced resistance, which may improve memory device connectivity, among other examples. Additionally, or alternatively, the thickness of the conductive liner 315 may remain above a threshold thickness at each corner and junction region, including the regions where the curved shape transitions to the straight segments (e.g., at the edges of the third level 305-c and the first level 305-a or the second level 305-b). The maintained thickness in these regions may further improve conductivity and may further reduce resistance as compared with other systems in which the liner may be deposited as two or more separate segments with varying thickness and contact at the junction regions.

By forming the conductive liner 315 continuously along the channel and junction regions, as well as forming and removing the various other liners, including the layers of protective material 210 and 310, as described, the conductive liner 315 may be continuous and deposited in a single deposition process (e.g., as compared with two separate depositions of conductive liners that may have relatively unreliable contact points) and may support continued current flow (e.g., with reduced resistance) to improve memory connectivity.

FIGS. 4A through 4G show examples of fabrication operations (e.g.,

manufacturing operations) that support improving continuity in memory arrays in accordance with examples as disclosed herein. For example, FIGS. 4A through 4G may illustrate aspects of sequences of operations for fabricating aspects of a memory array 200, which may be an example of implementing aspects of a memory device 100 as described with reference to FIG. 1, among other types of memory architectures.

Each of FIGS. 4A through 4G may illustrate aspects of a portion of a memory array 200 after different subsets of fabrication operations for forming the memory array 200. For example, FIG. 4A may illustrate the memory array 200-o after a first set of fabrication operations, FIG. 4B may illustrate the memory array 200-p after a second set of fabrication operations, and so on. Each view of the figures may be described with reference to an x-direction, a y-direction, and a z-direction, as illustrated. FIGS. 4A through 4G may be a cross sectional view (e.g., viewed according to the z-axis in the vertical direction, the y-axis in the horizontal direction, and the x-axis going into the page) of the memory array 200.

The fabrication operations described with reference to FIGS. 4A through 4G may be performed after the operations described with reference to FIG. 2G. For example, after the memory array 200-g is formed, as described with referenced to FIG. 2G, the memory array 200-g may undergo another set of fabrication operations to generate a conductive connecting memory channel, as described with reference to FIGS. 4A through 4G. In some examples, FIGS. 4A through 4G may represent a second example process for generating a conductive connecting memory channel, but other alternative processes may be supported. For example, FIGS. 3A through 3G as well as FIGS. 5A through 5D may illustrate other (e.g., alternative) processes for generating a conductive connecting memory channel as described herein.

Operations illustrated in and described with reference to FIGS. 4A through 4G may be performed by a manufacturing system, such as a semiconductor fabrication system configured to perform additive operations (e.g., deposition, epitaxy, bonding), subtractive operations (e.g., etching, trenching, planarizing, polishing, exhuming), modifying operations (e.g., oxidizing, doping, reacting, converting), and supporting operations (e.g., masking, patterning, photolithography, aligning), among other operations that support the described techniques. In some examples, operations performed by such a manufacturing system may be supported by a process controller or its components as described herein.

Although aspects of the memory array 200 illustrate examples of relative dimensions and quantities of various features, aspects of the memory array 200 may be implemented with other relative dimensions or quantities of such features in accordance with examples as disclosed herein. In the following description of the memory array 200, some methods, techniques, processes, and operations may be performed in different orders, or at different times, or otherwise modified. Further, some operations for fabricating a memory array 200 (e.g., for fabrication in accordance with an array architecture) may be omitted from the described fabrication operations, or other operations may be added to the described fabrication operations.

FIG. 4A illustrates an example of the memory array (e.g., as a memory array 200-o) after a first set of one or more fabrication operations (e.g., after a first set of one or more fabrication operations are performed to the memory array 200-g illustrated in FIG. 2G). For example, the memory array 200-o may include a stack 205-a of material including a set of oxide layers 230 and metal layers 235 formed above a substrate (e.g., semiconductor substrate, a semiconductor wafer). The stack 205-a may include the pillar 240 that extends through the stack 205-a. The pillar 240 may include the oxide material 245 and the layer of protective material 210 positioned between the oxide material 245 and sidewalls of the stack 205-a. The pillar 240 may additionally include the oxide liner 215, the nitride liner 220, and the sacrificial liner 225, each of which may extend along sidewalls of the stack 205-a. The sacrificial liner 225 may further extend along a top portion of the stack 205-a, as described with reference to FIG. 2A. The nitride liner 220 may extend to a bottom layer of the stack 205-b. The pillar 240 may further include the recess 241, which may be an absence of material above the oxide material, the layer of protective material 210, and the oxide liner. The memory array 200-o may further include the second stack 205-b of material including alternating oxide layers 230 and metal layers 235 formed above the stack 205-a and the recess 241. The second stack 205-b may include a cavity 251 that extends through the second stack 205-b. The cavity 251 may extend through the second stack 205-b of alternating oxide layers 230 and metal layers 235 and may further extend into the recess 241, in some examples. The cavity 251 may be a recess, hole, via, or other absence of material within a center portion of the stack 205-b.

After the set of one or more fabrication operations described herein, the memory array 200-o may include the recess 241. That is, the sacrificial material 250 may be removed from the recess 241. The set of fabrication operations may include, in some examples, a sacrificial material exhume process (e.g., an aluminum oxide exhume or a silicon nitride exhume, among other examples). For example, the sacrificial material 250 may be removed from the recess 241 via the exhume process, leaving the empty recess 241.

FIG. 4B illustrates an example of the memory array (e.g., as a memory array 200-p) after a second set of one or more fabrication operations. After the second set of one or more fabrication operations described herein, the memory array 200-p may include the oxide liner 425 and the layer of protective material 410. The oxide liner 425 may extend along sidewalls of the stack 205-b within the cavity 251 and along sidewalls of the recess 241. For example, the oxide liner 425 may include a layer of oxide material that may be deposited along a bottom surface of the recess 241 (e.g., on top of the oxide material 245, the layer of protective material 210, and the oxide liner 215 within the pillar), along sidewalls of the recess 241 (e.g., along sidewalls of the nitride liner 220 and a portion of a bottom oxide layer 230 of the stack 205-b), along sidewalls of the cavity 251 (e.g., along sidewalls of the oxide layers 230 and metal layers 235 in the stack 205-b, and along a top surface of the stack 205-b. The memory array 200-p may further include another layer of protective material 410 that extends continuously along the oxide liner 425. For example, the layer of protective material 410 may include a layer of protective material that may be deposited on top of the oxide liner 425. The oxide liner 425 may thereby extend between the layer of protective material 410 and the bottom of the recess 241, the sidewalls of the recess 241, as well as the sidewalls and top surface of the second stack 205-b.

In some examples, the second set of fabrication operations may include depositing an oxide material in the cavity 251 and the recess 241 to form the oxide liner 425. The set of operations may include depositing a protective material on top of the oxide liner 425 in the cavity 251 and the recess 241 to form the layer of protective material 410. In some examples, one or more planarization techniques may be performed to provide for relatively even thickness of the oxide liner 425 and the layer of protective material 410 within the cavity 251, within the recess 241, and on top of the stack 205-b.

FIG. 4C illustrates an example of the memory array (e.g., as a memory array 200-q) after a third set of one or more fabrication operations. After the third set of one or more fabrication operations described herein, the memory array 200-q, a portion of a bottom surface of the recess 241 may include or be in direct contact with the oxide material 245 in the pillar 240. For example, after the third set of one or more fabrication operations, a portion of the oxide liner 425 and the layer of protective material 410 may be removed. Remaining portions of the oxide liner 425 and the layer of protective material 410 may extend along the top surface of the stack 205-b, the sidewalls of the stack 205-b within the cavity 251, sidewalls of the recess 241 (e.g., along a bottom surface of a first oxide layer 230 in the stack 205-b, along the nitride liner 220), and along a portion of a bottom sidewall of the recess 241 (e.g., on top of the oxide liner 215 and the layer of protective material 210). In some examples, the oxide liner 425 and the layer of protective material 410 may extend over a portion of the oxide material 245 in the pillar 240, or the oxide liner 425 and the layer of protective material 410 may not be in contact with the oxide material 245 after the third set of one or more fabrication operations. In either case, the oxide liner 425 and the layer of protective material 410 may end relatively abruptly, such that edges of the oxide liner 425 and the layer of protective material 410 may be relatively straight within the recess 241.

The third set of one or more fabrication operations may include an etch procedure, in some examples. For example, the portion of the oxide liner 425 and the portion of the layer of protective material 410 may be removed via the etch procedure, which may be a punch etch, in some examples. The punch etch may selectively remove only the portion of the oxide liner 425 and the portion of the layer of protective material 410 positioned above the oxide material 245 in the pillar 240. Other portions of the oxide liner 425 and the layer of protective material 410, as well as other materials in the stack, may not be removed via the punch etch.

FIG. 4D illustrates an example of the memory array (e.g., as a memory array 200-r) after a fourth set of one or more fabrication operations. After the fourth set of one or more fabrication operations described herein, the memory array 200-r, may no longer include the oxide material 245, the layer of protective material 210, nor the layer of protective material 410. Additionally, after the fourth set of one or more fabrication operations, the oxide liner 425 may not extend within the recess 241. That is, a portion of the oxide liner 425 may be removed, such that the remaining oxide liner 425 extends along the top surface of the stack 205-b and along sidewalls of the stack 205-b within the cavity 251 until a bottom surface of a first oxide layer 230 of the stack 205-b. The recess 241 may thereby include an absence of material, and sidewalls of the recess 241 after the fourth set of fabrication operations may include a bottom edge of the oxide liner 425, a portion of a bottom surface of the first oxide layer 230 in the stack 205-b, a portion of the sidewall of the nitride liner 220, and a top portion of the oxide liner 215.

In some examples, the fourth set of one or more fabrication operations may include one or more exhume processes. For example, the oxide material 245 may be removed, via the cavity 251, from the pillar 240 and the recess 241. The exhume process may remove any exposed oxide materials in the material formation. The layer of protective material 210 may protect the oxide liner 215 from being removed as part of the exhume process. Similarly, the layer of protective material 410 may protect the portion of the oxide liner 425 along the sidewalls of the stack 205-b from being removed as part of the exhume process. However, the oxide exhume may remove the portion of the oxide liner 425 that is within the recess 241. For example, the oxide material 245 may be exhumed from the pillar 240 and from the edge of the oxide liner 425 that is exposed after the punch etch, through to the top of the recess 241. The portion of the oxide liner 425 that extends below the layer of protective material 410 in the recess 241 (e.g., oxide fangs) may be exposed via the edge prior to the exhume (e.g., due to the previous punch etch) and may thereby be removed during the exhume process, which may further increase a size of the recess 241. In some examples, a portion of the oxide liner 425 may remain and may extend into the recess after the oxide exhume. For example, a portion of the oxide liner 425 may extend below the bottom surface of the first layer of the stack 205-b and into the recess 241. The portion of the oxide liner 425 may be relatively straight and may not bend or curve under the first layer of the stack 205-b.

In some examples, the fourth set of one or more fabrication operations may further include a protective material removal process. For example, the protective material may be removed, via the cavity 251, from along the sidewalls of the stack 205-a (e.g., from the pillar 240), from the recess 241, from the sidewalls of the stack 205-b in the cavity 251, and from the top surface of the stack 205-b. The removal process may be an exhume process, and etch process, or some other technique for removing any exposed protective material (e.g., polymer or some other type of material). The removal process may remove a portion of the layer of protective material 410 that extends into the recess 241, as well as a portion of the layer of protective material 410 that is positioned above the recess 241 (e.g., in a first layer of the second stack 205-b). The removal process may not remove other materials from the memory array 200-r. For example, the oxide liner 425 may remain along the sidewalls of the stack 205-b within the cavity 251 and along a top surface of the stack 205-b.

In some examples, after removal of the oxide material 245, the cavity 251 may expand. For example, the cavity 251, which may also be referred to as a pillar in some examples herein, may extend from the top surface of the stack 205-b to a bottom surface of the stack 205-a (e.g., through or including the recess 241).

FIG. 4E illustrates an example of the memory array (e.g., as a memory array 200-s) after a fifth set of one or more fabrication operations. After the fifth set of one or more fabrication operations described herein, the memory array 200-s may additionally include a conductive liner 415 that extends along sidewalls of the stack 205-b, the stack 205-a, and the recess 241. For example, the conductive liner 415 may include a conductive material (e.g., polymer, or some other type of material) that is deposited along a top surface of the stack 205-b (e.g., above the oxide liner 425), along sidewalls of the stack 205-b and the stack 205-a within the cavity 251 (e.g., on top of the oxide liner 425) and along sidewalls of the recess 241.

In some examples, the fifth set of operations may include a deposition process (e.g., a polymer deposition reflow). For example, the conductive material may be deposited within the cavity 251 and the recess 241. The conductive material may contact the oxide liner 425 on top of the stack 205-b and along the sidewalls of the stack 205-b within the cavity 251. The conductive material may further contact, after deposition, a portion of a bottom surface of the first layer (e.g., an oxide layer 230) in the second stack 205-b, a portion of sidewalls of the nitride liner 220 in a top portion of the stack 205-a, and then the oxide liner 215 along remaining sidewalls of the stack 205-a within the cavity 251.

In some examples, the conductive liner 415 may include a first segment that extends along the sidewall of the stack 205-b (e.g., a first level). The first segment may be relatively straight. In some examples, the first segment may extend along the sidewall of the stack 205-b on each side of the cavity 251. The first segment may additionally extend along a top surface of the stack 205-b. The conductive liner 415 may further include a second segment that extends along the sidewall of the stack 205-a (e.g., a second level). The second segment may be relatively straight. The conductive liner 415 may further include a third segment that curves or otherwise extends along the sidewalls in the recess 241 (e.g., a third level, a connecting or junction region). For example, the conductive liner 415 may include a relatively straight portion under the oxide liner 425, which may curve or otherwise expand to contact and extend along a bottom surface of the first oxide layer 230 in the second stack 205-b, which may curve into another relatively straight portion along a portion of the sidewall of the nitride liner 220 in the recess, which may further curve over a top surface of the oxide liner 215 in the recess and may curve into the second straight segment along the sidewalls of the stack 205-a. The conductive liner 415 may thereby have a somewhat curved shape within the recess 241. In some examples, the conductive liner may include three relatively straight segments connected via curved corners after the deposition.

FIG. 4F illustrates an example of the memory array (e.g., as a memory array 200-t) after a sixth set of one or more fabrication operations. After the sixth set of one or more fabrication operations described herein, the conductive liner 415 of the memory array 200-t may have a second thickness that may be less than a first thickness of the conductive liner 415 before the sixth set of one or more fabrication operations.

In some examples, the sixth set of operations may include an etch or cut process, such as a ULC wet cut. For example, the conductive liner 415 may be cut or refined to reduce the thickness. In some examples, the thickness may be constant or within a threshold thickness range across all of the conductive liner 415. Additionally, or alternatively, the thickness of the conductive liner 415 in the recess 241, for example, may be different than the thickness of the conductive liner 415 in the first stack 205-a.

FIG. 4G illustrates an example of the memory array (e.g., as a memory array 200-u) after a seventh set of one or more fabrication operations. For example, the memory array 200-u may include a stack 205-a of material including a set of oxide layers 230 and metal layers 235 formed above a substrate (e.g., semiconductor substrate, a semiconductor wafer). The stack 205-a may include a pillar that extends through the stack 205-a. The pillar may include the oxide liner 215, the nitride liner 220, and the sacrificial liner 225, each of which may extend along sidewalls of the stack 205-a. The sacrificial liner 225 may further extend along a top portion of the stack 205-a (e.g., between the stack 205-a and the stack 205-b). The memory array 200-u may further include the second stack 205-b of material including alternating oxide layers 230 and metal layers 235 formed above the stack 205-a. The second stack 205-b may include a remaining portion of the pillar that extends through the stacks 205-a and 205-b and is filled with an oxide liner 425 that extends along sidewalls of the stack 205-b, as well as the oxide material 420 and the conductive material 430. In some examples, after the seventh set of one or more fabrication operations, the oxide liner 425 may be removed from the top surface of the stack 205-b.

In some examples, the memory array 200-u may represent a stack of materials, and the stack of materials may include three levels 405, including a first level 405-a, a second level 405-b, and a third level 405-c. In some examples, the third level 405-c of the stack may include a junction region that connects the first level 305-a and the second level 305-b. The first level 305-a may include the first segment of the conductive liner 415 that extends along sidewalls of the stack 205-b, as described with reference to FIG. 4E. The second level 405-b may include the second segment of the conductive liner 415 that extends along sidewalls of the stack 205-a, as described with reference to FIG. 4E. The third level 405-c may include the third segment of the conductive liner 415 that curves or otherwise bends along the sidewalls of the recess 241 (e.g., now the junction region within the pillar), as described with reference to FIG. 4E. The third segment of the conductive liner 415 may be coupled with a portion of a bottom surface of the first oxide layer 230 of the stack 205-b, the bottom surface of the oxide liner 425, a portion of the sidewalls of the nitride liner 220, and a top portion of the oxide liner 215.

After the seventh set of one or more fabrication operations, the memory array 200-u may include an oxide material 420 that extends through the second level 305-b, the third level 305-c, and a portion of the first level 305-a (e.g., that fills the previously described cavity 251 and recess 241). The memory array 200-u may further include a conductive material 430 positioned above the oxide material 420 in the first level 405-a. The conductive material 430, the oxide material 420, and the conductive liner 415 may form a pillar that extends through the levels of the stack, in some examples. In some examples, the pillar may include a first width 455-a in the first level 405-a of the stack, a second width 455-b in the second level 405-b of the stack, and one or more third widths 455-c in the third level 405-c of the stack. For example, because the third level 405-c includes the curved sidewalls and corners, it is to be understood that the pillar (e.g., including the oxide material 420) in the third level 305-c may include varying widths.

The seventh set of one or more fabrication operations described herein may include a metallization (e.g., replacement gate) operation, in some examples. During the metallization procedure, the metal layers 235 (e.g., nitride layers) may be removed to form a set of cavities. Subsequently, a metal may be deposited into the cavities to form second metal layers 435 (e.g., word lines 165). The oxide material 420 may then be deposited in the cavity to form the conductive pillar including the conductive liner 415 and the oxide material 420. The second metal layers 435 may be configured to couple the conductive pillar with supporting circuitry (e.g., word line drivers, among other circuitry). The conductive material 430 deposited at the top of the conductive pillar may be configured to couple the conductive pillar with other supporting circuitry or access lines (e.g., a bit line).

The described techniques may thereby provide for formation of a continuous conductive channel or pillar that extends through two separate stacks of memory material and a junction region. By forming the conductive liner 415 continuously along the channel and junction regions, as well as forming and removing the various other liners, including the layers of protective material 210 and 410, as described, the conductive liner 415 may be continuous and may support continued current flow (e.g., with reduced resistance) to improve memory connectivity.

The second example process for generating the conductive connecting memory channel (e.g., the pillar including the oxide material 420, the conductive liner 415, and the conductive material 430), as described with reference to FIGS. 4A through 4G, may result in a conductive memory channel having a joint connecting region (e.g., the third level 405-c) with a different shape than the joint connecting region (e.g., the third level 305-c) described with reference to FIG. 3G and produced via the first example process for generating the conductive memory channel as described with reference to FIGS. 3A through 3G. For example, the conductive liner 415 in the third level 405-c may include an exterior sidewall that is relatively straight and includes non-curved corner regions (e.g., a rounded rectangular shape). The exterior sidewall may be coupled with the bottom portion of the oxide liner 425, the portion of the bottom surface of the first layer in the stack 205-b, the sidewall of the nitride liner 220, and the top surface of the oxide liner 215. The conductive liner 415 in the third level 405-c may include an interior sidewall that is relatively straight with curved corner regions. The interior sidewall may be coupled with the oxide material 420.

The conductive channel may include two relatively straight segments connective by the rounded rectangular region. The rounded rectangular region may have multiple different widths 455-c, as described herein, due to the at least a portion of the region including a curved surface. The curved corners of this region may provide for reduced resistance within the conductive channel as compared to sharper angles and corners. In some examples, a thickness of the conductive liner 415 may vary within the rounded connecting region. For example, the conductive liner 415 may be relatively thick in the upper corners of the region (e.g., between the oxide liner 425, the first layer of the stack 205-b, and the nitride liner 220), and may be relatively thinner along the nitride liner 220, where the shape is straighter. The enhanced thickness in the corner and curved portions may provide for improved conductivity and reduced resistance, which may improve memory device connectivity, among other examples. Additionally, or alternatively, the thickness of the conductive liner 415 may remain above a threshold thickness at each corner and junction region, including the regions where the rounded rectangular shape transitions to the straight segments (e.g., at the edges of the third level 405-c and the first level 405-a or the second level 405-b). The maintained thickness in these regions due to the singular deposition of the conductive liner 415 may further improve conductivity and may further reduce resistance as compared with other systems in which the liner may be deposited as two or more separate segments with varying thickness and contact at the junction regions.

In contrast, the conductive liner 315 in the third level 305-c in the memory array 200-n illustrated in FIG. 3G may include curved interior and exterior sidewalls and corresponding corner regions. For example, the exterior sidewalls of the conductive liner 315 in the third level 305-c may curve due to, for example, the formation of the cavities 242 in the bottom layer of the stack 205-b.

A third example process for generating the conductive connecting memory channel may be described with reference to FIGS. 5A through 5D and may result in a third example shape of the connecting region.

FIGS. 5A through 5D show examples of fabrication operations (e.g., manufacturing operations) that support improving continuity in memory arrays in accordance with examples as disclosed herein. For example, FIGS. 5A through 5D may illustrate aspects of sequences of operations for fabricating aspects of a memory array 200, which may be an example of implementing aspects of a memory device 100 as described with reference to FIG. 1, among other types of memory architectures.

Each of FIGS. 5A through 5D may illustrate aspects of a portion of a memory array 200 after different subsets of fabrication operations for forming the memory array 200. For example, FIG. 5A may illustrate the memory array 200-v after a first set of fabrication operations, FIG. 5B may illustrate the memory array 200-w after a second set of fabrication operations, and so on. Each view of the figures may be described with reference to an x-direction, a y-direction, and a z-direction, as illustrated. FIGS. 5A through 5D may be a cross sectional view (e.g., viewed according to the z-axis in the vertical direction, the y-axis in the horizontal direction, and the x-axis going into the page) of the memory array 200.

The fabrication operations described with reference to FIGS. 5A through 5D may be performed after the operations described with reference to FIG. 4C. For example, after the memory array 200-q is formed, as described with referenced to FIG. 4C, the memory array 200-q may undergo another set of fabrication operations to generate a conductive connecting memory channel, as described with reference to FIGS. 5A through 5D. In some examples, FIGS. 5A through 5D may represent a second example process for generating a conductive connecting memory channel, but other alternative processes may be supported. For example, FIGS. 3A through 3G as well as FIGS. 4D through 4G may illustrate other (e.g., alternative) processes for generating a conductive connecting memory channel as described herein.

Operations illustrated in and described with reference to FIGS. 5A through 5D may be performed by a manufacturing system, such as a semiconductor fabrication system configured to perform additive operations (e.g., deposition, epitaxy, bonding), subtractive operations (e.g., etching, trenching, planarizing, polishing, exhuming), modifying operations (e.g., oxidizing, doping, reacting, converting), and supporting operations (e.g., masking, patterning, photolithography, aligning), among other operations that support the described techniques. In some examples, operations performed by such a manufacturing system may be supported by a process controller or its components as described herein.

Although aspects of the memory array 200 illustrate examples of relative dimensions and quantities of various features, aspects of the memory array 200 may be implemented with other relative dimensions or quantities of such features in accordance with examples as disclosed herein. In the following description of the memory array 200, some methods, techniques, processes, and operations may be performed in different orders, or at different times, or otherwise modified. Further, some operations for fabricating a memory array 200 (e.g., for fabrication in accordance with an array architecture) may be omitted from the described fabrication operations, or other operations may be added to the described fabrication operations.

FIG. 5A illustrates an example of the memory array (e.g., as a memory array 200-v) after a fourth set of one or more fabrication operations (e.g., after a fourth set of one or more fabrication operations are performed to the memory array 200-q illustrated in FIG. 4C). For example, after the fourth set of one or more fabrication operations, the memory array 200-v may no longer include the oxide material 245, the layer of protective material 210, nor the layer of protective material 410. Additionally, after the fourth set of one or more fabrication operations, the oxide liner 425 may not extend within the recess 241. That is, a portion of the oxide liner 425 may be removed, such that the remaining oxide liner 425 extends along the top surface of the stack 205-b and along sidewalls of the stack 205-b within the cavity 251 until a bottom surface of a first oxide layer 230 of the stack 205-b. A portion of the nitride liner 220 may further be removed within the recess 241. For example, after the fourth set of one or more fabrication operations, the nitride liner 220 may extend along the sidewalls of the stack 205-a from the bottom surface of the stack to a bottom surface of the recess 241. In some examples, a top surface of the nitride liner 220 may be relatively even with a top surface of the oxide liner 215 after the first set of fabrication operations. The recess 241 may thereby include an absence of material, and sidewalls of the recess 241 after the fourth set of fabrication operations may include a bottom edge of the oxide liner 425, a portion of a bottom surface of the first oxide layer 230 in the stack 205-b, a portion of the sidewall of the sacrificial liner 225, a top portion of the nitride liner 220, and a top portion of the oxide liner 215.

In some examples, the fourth set of one or more fabrication operations may include one or more exhume processes. For example, the oxide material 245 may be removed, via the cavity 251, from the pillar 240 and the recess 241. The exhume process may remove any exposed oxide materials in the material formation. The layer of protective material 210 may protect the oxide liner 215 from being removed as part of the exhume process. Similarly, the layer of protective material 410 may protect the portion of the oxide liner 425 along the sidewalls of the stack 205-b from being removed as part of the exhume process. However, the oxide exhume may remove the portion of the oxide liner 425 that is within the recess 241. For example, the oxide material 245 may be exhumed from the pillar 240 and from the edge of the oxide liner 425 that is exposed after the punch etch, through to the top of the recess 241. The portion of the oxide liner 425 that extends below the layer of protective material 410 in the recess 241 (e.g., oxide fangs) may be exposed via the edge prior to the exhume (e.g., due to the previous punch etch) and may thereby be removed during the exhume process, which may further increase a size of the recess 241.

In some examples, the fourth set of one or more fabrication operations may further include a protective material removal process. For example, the protective material may be removed, via the cavity 251, from along the sidewalls of the stack 205-a (e.g., from the pillar 240), from the recess 241, from the sidewalls of the stack 205-b in the cavity 251, and from the top surface of the stack 205-b. The removal process may be an exhume process, an etch process, or some other technique for removing any exposed protective material (e.g., polymer or some other type of material). The removal process may remove a portion of the layer of protective material 410 that extends into the recess 241, as well as a portion of the layer of protective material 410 that is positioned above the recess 241 (e.g., in a first layer of the second stack 205-b). The removal process may not remove other materials from the memory array 200-v. For example, the oxide liner 425 may remain along the sidewalls of the stack 205-b within the cavity 251 and along a top surface of the stack 205-b.

In some examples, the fourth set of one or more fabrication operations may further include a nitride removal process (e.g., a silicon nitride removal). For example, after the removal of the oxide material 245, the portion of the oxide liner 425, the layer of protective material 410, and the layer of protective material 210, a portion of the nitride liner 220 that is exposed may also be removed. The nitride removal may be another exhume or etch process that removes the portion of the nitride liner 220 from the recess 241. The remaining nitride liner 220 may extend between the sacrificial liner 225 and the oxide liner 215. The removal of the nitride liner 220 may expand a size or area of the recess 241 as compared with the processes described with reference to FIG. 4D, in which the nitride liner 220 is not removed.

In some examples, after removal of the oxide material 245, the cavity 251 may expand. For example, the cavity 251, which may also be referred to as a pillar in some examples herein, may extend from the top surface of the stack 205-b to a bottom surface of the stack 205-a (e.g., through or including the recess 241).

FIG. 5B illustrates an example of the memory array (e.g., as a memory array 200-w) after a fifth set of one or more fabrication operations. After the fifth set of one or more fabrication operations described herein, the memory array 200-w may additionally include a conductive liner 515 that extends along sidewalls of the stack 205-b, the stack 205-a, and the recess 241. For example, the conductive liner 515 may include a conductive material (e.g., polymer, or some other type of material) that is deposited along a top surface of the stack 205-b (e.g., above the oxide liner 425), along sidewalls of the stack 205-b and the stack 205-a within the cavity 251 (e.g., on top of or otherwise replacing the oxide liner 425) and along sidewalls of the recess 241.

In some examples, the fifth set of one or more fabrication operations may include a deposition process (e.g., a polymer deposition reflow). For example, the conductive material may be deposited within the cavity 251 and the recess 241. The conductive material may contact the oxide liner 425 on top of the stack 205-b and along the sidewalls of the stack 205-b within the cavity 251. The conductive material may further contact, after deposition, a portion of a bottom surface of the first layer (e.g., an oxide layer 230) in the second stack 205-b, a portion of sidewalls of the sacrificial liner 225 in a top portion of the stack 205-a, a top portion of the nitride liner 220, and then the oxide liner 215 along remaining sidewalls of the stack 205-a within the cavity 251.

In some examples, the conductive liner 515 may include a first segment that extends along the sidewall of the stack 205-b (e.g., a first level). The first segment may be relatively straight. In some examples, the first segment may extend along the sidewall of the stack 205-b on each side of the cavity 251. The first segment may additionally extend along a top surface of the stack 205-b. The conductive liner 515 may further include a second segment that extends along the sidewall of the stack 205-a (e.g., a second level). The second segment may be relatively straight. The conductive liner 515 may further include a third segment that curves or otherwise extends along the sidewalls in the recess 241 (e.g., a third level, a connecting or junction region). For example, the conductive liner 515 may include a relatively straight portion along a bottom surface of the first oxide layer 230 in the second stack 205-b, which may curve into another relatively straight portion along a portion of the sidewall of the sacrificial liner 225 in the recess 241, which may further curve over a top surface of the nitride liner 220 and the oxide liner 215 in the recess 241 and may curve into the second straight segment along the sidewalls of the stack 205-a (e.g., along the sidewalls of the oxide liner 215). The conductive liner 515 may thereby have a somewhat curved shape within the recess 241. At least an interior sidewall of the conductive liner 515 may include at least some curved portions (e.g., curved corners). The exterior sidewall of the conductive liner 515 may match the shape of the materials on which it is deposited, which may be relatively straight (e.g., the bottom surface of the first layer of the stack 205-b, the sidewall of the sacrificial liner 225) or somewhat curved (e.g., the top surface of the nitride liner 220, the top surface of the oxide liner 215). In some examples, the third segment of the conductive liner 515 may include three relatively straight segments connected via curved corners after the deposition.

FIG. 5C illustrates an example of the memory array (e.g., as a memory array 200-x) after a sixth set of one or more fabrication operations. After the sixth set of one or more fabrication operations described herein, the conductive liner 515 of the memory array 200-x may have a second thickness that may be less than a first thickness of the conductive liner 515 before the sixth set of one or more fabrication operations.

In some examples, the sixth set of operations may include an etch or cut process, such as a ULC wet cut. For example, the conductive liner 515 may be cut or refined to reduce the thickness. In some examples, the thickness may be constant or within a threshold thickness range across all of the conductive liner 515. Additionally, or alternatively, the thickness of the conductive liner 515 in the recess 241, for example, may be different than the thickness of the conductive liner 515 in the first stack 205-a.

FIG. 5D illustrates an example of the memory array (e.g., as a memory array 200-y) after a seventh set of one or more fabrication operations. For example, the memory array 200-y may include a stack 205-a of material including a set of oxide layers 230 and metal layers 235 formed above a substrate (e.g., semiconductor substrate, a semiconductor wafer). The stack 205-a may include a pillar that extends through the stack 205-a. The pillar may include the oxide liner 215, the nitride liner 220, and the sacrificial liner 225, each of which may extend along sidewalls of the stack 205-a. The sacrificial liner 225 may further extend along a top portion of the stack 205-a (e.g., between the stack 205-a and the stack 205-b). The memory array 200-y may further include the second stack 205-b of material including alternating oxide layers 230 and metal layers 235 formed above the stack 205-a. The second stack 205-b may include a remaining portion of the pillar that extends through the stacks 205-a and 205-b and is filled with the oxide material 520 and the conductive material 530. In some examples, after the seventh set of one or more fabrication operations, the oxide liner 425 may be removed from the top surface of the stack 205-b.

In some examples, the memory array 200-y may represent a stack of materials, and the stack of materials may include three levels 505, including a first level 505-a, a second level 505-b, and a third level 505-c. In some examples, the third level 505-c of the stack may include a junction region that connects the first level 505-a and the second level 505-b. The first level 505-a may include the first segment of the conductive liner 515 that extends along sidewalls of the stack 205-b, as described with reference to FIG. 3E. The second level 505-b may include the second segment of the conductive liner 515 that extends along sidewalls of the stack 205-a, as described with reference to FIG. 3E. The third level 505-c may include the third segment of the conductive liner 515 that curves or otherwise bends along the sidewalls of the recess 241 (e.g., now the junction region within the pillar), as described with reference to FIG. 3E. The third segment of the conductive liner 415 may be coupled with a portion of a bottom surface of the first oxide layer 230 of the stack 205-b, a portion of the sidewalls of the sacrificial liner 225, a top portion of the nitride liner 220, and a top portion of the oxide liner 215.

After the seventh set of one or more fabrication operations, the memory array 200-y may include an oxide material 520 that extends through the second level 505-b, the third level 505-c, and a portion of the first level 505-a (e.g., that fills the previously described cavity 251 and recess 241). The memory array 200-y may further include a conductive material 530 positioned above the oxide material 520 in the first level 505-a. The conductive material 530, the oxide material 520, and the conductive liner 515 may form a pillar that extends through the levels of the stack, in some examples. In some examples, the pillar may include a first width 555-a in the first level 505-a of the stack, a second width 555-b in the second level 505-b of the stack, and one or more third widths 555-c in the third level 505-c of the stack. For example, because the third level 505-c includes the curved corners, it is to be understood that the pillar (e.g., including the oxide material 520) in the third level 505-c may include varying widths.

The seventh set of one or more fabrication operations described herein may include a metallization (e.g., replacement gate) operation, in some examples. During the metallization procedure, the metal layers 235 (e.g., nitride layers) may be removed to form a set of cavities. Subsequently, a metal may be deposited into the cavities to form second metal layers 535 (e.g., word lines 165). The oxide material 520 may then be deposited in the cavity to form the conductive pillar including the conductive liner 515 and the oxide material 520. The second metal layers 535 may be configured to couple the conductive pillar with supporting circuitry (e.g., word line drivers, among other circuitry). The conductive material 530 deposited at the top of the conductive pillar may be configured to couple the conductive pillar with other supporting circuitry or access lines (e.g., a bit line).

The described techniques may thereby provide for formation of a continuous conductive channel or pillar that extends through two separate stacks of memory material and a junction region. By forming the conductive liner 515 continuously along the channel and junction regions, as well as forming and removing the various other liners, including the layers of protective material 210 and 410, as described, the conductive liner 515 may be continuous and may support continued current flow (e.g., with reduced resistance) to improve memory connectivity.

The third example process for generating the conductive connecting memory channel (e.g., the pillar including the oxide material 520, the conductive liner 515, and the conductive material 530), as described with reference to FIGS. 5A through 5D, may result in a conductive memory channel having a joint connecting region (e.g., the third level 505-c) with a different shape than the joint connecting region (e.g., the third level 305-c) described with reference to FIG. 3G and produced via the first example process for generating the conductive memory channel as described with reference to FIGS. 3A through 3G and with a different shape than the joint connecting region (e.g., the third level 405-c) described with reference to FIG. 4G and produced via the second example process for generating the conductive connecting memory channel as described with reference to FIGS. 4A through 4G. For example, the conductive liner 515 in the third level 505-c may include an exterior sidewall that is relatively straight and includes non-curved corner regions (e.g., a rounded rectangular shape with increased thickness of the conductive liner 515 relative to the memory array illustrated in FIG. 4G). The exterior sidewall may be coupled with the portion of the bottom surface of the first layer in the stack 205-b, the sidewall of the sacrificial liner 225, the top surface of the nitride liner 220, and the top surface of the oxide liner 215. The conductive liner 515 in the third level 505-c may include an interior sidewall that is relatively straight with curved corner regions. The interior sidewall may be coupled with the oxide material 520.

The conductive channel may include two relatively straight segments connective by the rounded rectangular region. The rounded rectangular region may have multiple different widths 555-c, as described herein, due to the at least a portion of the region including a curved surface. The curved corners of this region may provide for reduced resistance within the conductive channel as compared to sharper angles and corners. In some examples, a thickness of the conductive liner 515 may vary within the rounded connecting region. For example, the conductive liner 515 may be relatively thick in the upper corners of the region (e.g., between the first layer of the stack 205-b, and the sacrificial liner 225), and may be relatively thinner along the nitride liner sidewall of the sacrificial liner 225, where the shape is straighter. The enhanced thickness in the corner and curved portions may provide for improved conductivity and reduced resistance, which may improve memory device connectivity, among other examples. Additionally, or alternatively, the thickness of the conductive liner 515 may remain above a threshold thickness at each corner and junction region, including the regions where the rounded rectangular shape transitions to the straight segments (e.g., at the edges of the third level 505-c and the first level 505-a or the second level 505-b). The maintained thickness in these regions due to the singular deposition of the conductive liner 515 may further improve conductivity and may further reduce resistance as compared with other systems in which the liner may be deposited as two or more separate segments with varying thickness and contact at the junction regions.

The one or more third widths 555-c of the oxide material 520 within the third level 505-c may include a maximum width that is greater than a maximum width of the one or more third widths 455-c of the oxide material 420 within the third level 405-c illustrated in FIG. 4G. For example, because the portion of the nitride liner 220 is removed from the recess 241 in FIG. 5A, the size of the recess 241 may expand, which may result in a larger junction region than the junction region illustrated in FIG. 4G. Additionally, in some examples, the deposition of the conductive liner 515 may replace or otherwise remove the oxide liner 425, which may further increase the width 555-a and the widths 555-c relative to the width 455-a and the widths 455-c described with reference to FIG. 4G. Additionally, or alternatively, the removal of the portion of the nitride liner 220 may provide for increased thickness of the conductive liner 515 within the third level 505-c relative to the conductive liner 415, which may further improve continuity and reduce resistance.

In contrast, the conductive liner 315 in the third level 305-c in the memory array 200-n illustrated in FIG. 3G may include curved interior and exterior sidewalls and corresponding corner regions. For example, the exterior sidewalls of the conductive liner 315 in the third level 305-c may curve due to, for example, the formation of the cavities 242 in the bottom layer of the stack 205-b.

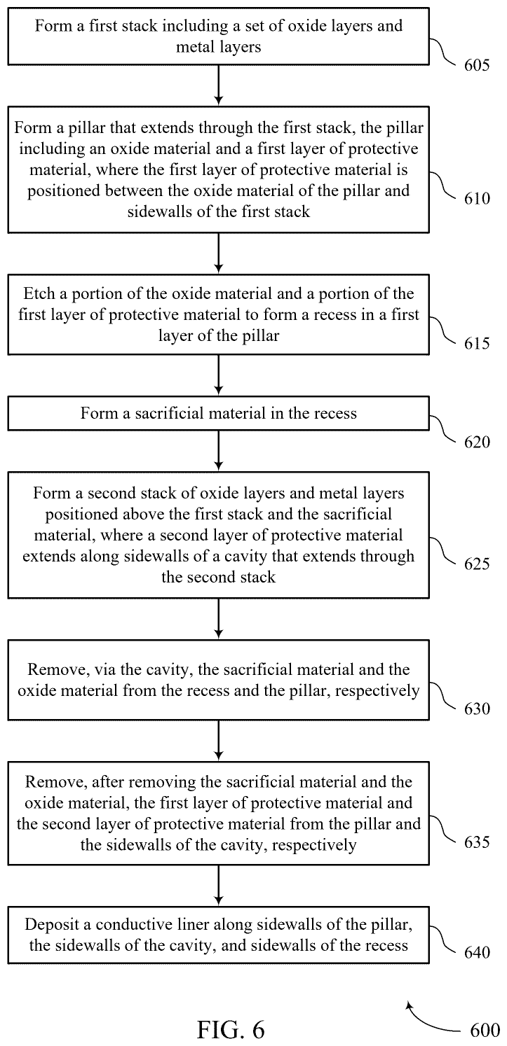

FIG. 6 shows a flowchart illustrating a method 600 that supports improving continuity in memory arrays in accordance with examples as disclosed herein. The operations of method 600 may be implemented by a manufacturing system or its components as described herein. In some examples, a manufacturing system may execute a set of instructions to control the functional elements of the device to perform the described functions. Additionally, or alternatively, the manufacturing system may perform aspects of the described functions using special-purpose hardware.

At 605, the method may include forming a first stack including a set of oxide layers and metal layers.

At 610, the method may include forming a pillar that extends through the first stack, the pillar including an oxide material and a first layer of protective material, where the first layer of protective material is positioned between the oxide material of the pillar and sidewalls of the first stack.

At 615, the method may include etching a portion of the oxide material and a portion of the first layer of protective material to form a recess in a first layer of the pillar.

At 620, the method may include forming a sacrificial material in the recess.

At 625, the method may include forming a second stack of oxide layers and metal layers positioned above the first stack and the sacrificial material, where a second layer of protective material extends along sidewalls of a cavity that extends through the second stack.

At 630, the method may include removing, via the cavity, the sacrificial material and the oxide material from the recess and the pillar, respectively.

At 635, the method may include removing, after removing the sacrificial material and the oxide material, the first layer of protective material and the second layer of protective material from the pillar and the sidewalls of the cavity, respectively.

At 640, the method may include depositing a conductive liner along sidewalls of the pillar, the sidewalls of the cavity, and sidewalls of the recess.

In some examples, an apparatus as described herein may perform a method or methods, such as the method 600. The apparatus may include features, circuitry, logic, means, or instructions (e.g., a non-transitory computer-readable medium storing instructions executable by a processor), or any combination thereof for performing the following aspects of the present disclosure:

Aspect 1: A method, apparatus, or non-transitory computer-readable medium including operations, features, circuitry, logic, means, or instructions, or any combination thereof for forming a first stack including a set of oxide layers and metal layers; forming a pillar that extends through the first stack, the pillar including an oxide material and a first layer of protective material, where the first layer of protective material is positioned between the oxide material of the pillar and sidewalls of the first stack; etching a portion of the oxide material and a portion of the first layer of protective material to form a recess in a first layer of the pillar; forming a sacrificial material in the recess; forming a second stack of oxide layers and metal layers positioned above the first stack and the sacrificial material, where a second layer of protective material extends along sidewalls of a cavity that extends through the second stack; removing, via the cavity, the sacrificial material and the oxide material from the recess and the pillar, respectively; removing, after removing the sacrificial material and the oxide material, the first layer of protective material and the second layer of protective material from the pillar and the sidewalls of the cavity, respectively; and depositing a conductive liner along sidewalls of the pillar, the sidewalls of the cavity, and sidewalls of the recess.

Aspect 2: The method, apparatus, or non-transitory computer-readable medium of aspect 1, further including operations, features, circuitry, logic, means, or instructions, or any combination thereof for forming an oxide liner along the sidewalls of the cavity and along a first surface of the sacrificial material; forming, after forming the oxide liner, the second layer of protective material along the oxide liner; and etching, via a punch etch, the second layer of protective material and the oxide liner to remove a portion of the second layer of protective material and a portion of the oxide liner along the first surface of the sacrificial material, where remaining portions of the second layer of protective material and the oxide liner remain along the sidewalls of the cavity, and where removing the sacrificial material via the cavity is based at least in part on removing the portion of the second layer of protective material and the portion of the oxide liner along the first surface of the sacrificial material.

Aspect 3: The method, apparatus, or non-transitory computer-readable medium of aspect 2, where removing the oxide material includes operations, features, circuitry, logic, means, or instructions, or any combination thereof for removing, as part of an oxide exhume after removing the sacrificial material, the oxide material via the cavity, where a portion of the oxide liner within the recess is removed based at least in part on the oxide exhume.

Aspect 4: The method, apparatus, or non-transitory computer-readable medium of any of aspects 1 through 3, further including operations, features, circuitry, logic, means, or instructions, or any combination thereof for etching, in accordance with a wet etch process after depositing the conductive liner, a portion of the conductive liner to reduce a width of the conductive liner along the sidewalls of the pillar, the sidewalls of the cavity, and sidewalls of the recess, where the sidewalls of the recess include curved sidewalls.

Aspect 5: The method, apparatus, or non-transitory computer-readable medium of any of aspects 1 through 4, further including operations, features, circuitry, logic, means, or instructions, or any combination thereof for depositing, after depositing the conductive liner, the oxide material in the pillar, the recess, and at least a portion of the cavity and depositing, after depositing the oxide material, a conductive material, where the conductive material fills a second portion of the cavity between the oxide material and a top layer of the second stack.

Aspect 6: The method, apparatus, or non-transitory computer-readable medium of any of aspects 1 through 5, further including operations, features, circuitry, logic, means, or instructions, or any combination thereof for performing, after depositing the conductive liner, a metallization process to remove a set of nitride layers from the first stack and the second stack to form a set of cavities and deposit a metal in each cavity of the set of cavities to form the metal layers, the metal layers forming a set of word lines.

Aspect 7: The method, apparatus, or non-transitory computer-readable medium of any of aspects 1 through 6, further including operations, features, circuitry, logic, means, or instructions, or any combination thereof for forming a set of memory cells at each layer of the oxide layers and the metal layers, where the conductive liner includes a memory channel for the set of memory cells.

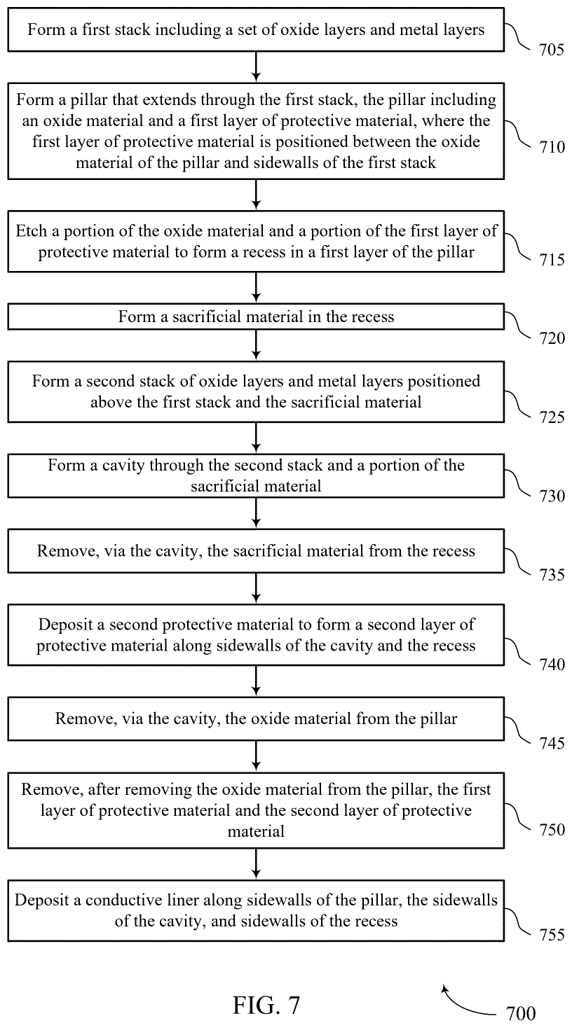

FIG. 7 shows a flowchart illustrating a method 700 that supports improving continuity in memory arrays in accordance with examples as disclosed herein. The operations of method 700 may be implemented by a manufacturing system or its components as described herein. In some examples, a manufacturing system may execute a set of instructions to control the functional elements of the device to perform the described functions. Additionally, or alternatively, the manufacturing system may perform aspects of the described functions using special-purpose hardware.

At 705, the method may include forming a first stack including a set of oxide layers and metal layers.

At 710, the method may include forming a pillar that extends through the first stack, the pillar including an oxide material and a first layer of protective material, where the first layer of protective material is positioned between the oxide material of the pillar and sidewalls of the first stack.

At 715, the method may include etching a portion of the oxide material and a portion of the first layer of protective material to form a recess in a first layer of the pillar.

At 720, the method may include forming a sacrificial material in the recess.

At 725, the method may include forming a second stack of oxide layers and metal layers positioned above the first stack and the sacrificial material.

At 730, the method may include forming a cavity through the second stack and a portion of the sacrificial material.

At 735, the method may include removing, via the cavity, the sacrificial material from the recess.

At 740, the method may include depositing a second protective material to form a second layer of protective material along sidewalls of the cavity and the recess.

At 745, the method may include removing, via the cavity, the oxide material from the pillar.

At 750, the method may include removing, after removing the oxide material from the pillar, the first layer of protective material and the second layer of protective material.

At 755, the method may include depositing a conductive liner along sidewalls of the pillar, the sidewalls of the cavity, and sidewalls of the recess.

In some examples, an apparatus as described herein may perform a method or methods, such as the method 700. The apparatus may include features, circuitry, logic, means, or instructions (e.g., a non-transitory computer-readable medium storing instructions executable by a processor), or any combination thereof for performing the following aspects of the present disclosure:

Aspect 8: A method, apparatus, or non-transitory computer-readable medium including operations, features, circuitry, logic, means, or instructions, or any combination thereof for forming a first stack including a set of oxide layers and metal layers; forming a pillar that extends through the first stack, the pillar including an oxide material and a first layer of protective material, where the first layer of protective material is positioned between the oxide material of the pillar and sidewalls of the first stack; etching a portion of the oxide material and a portion of the first layer of protective material to form a recess in a first layer of the pillar; forming a sacrificial material in the recess; forming a second stack of oxide layers and metal layers positioned above the first stack and the sacrificial material; forming a cavity through the second stack and a portion of the sacrificial material; removing, via the cavity, the sacrificial material from the recess; depositing a second protective material to form a second layer of protective material along sidewalls of the cavity and the recess; removing, via the cavity, the oxide material from the pillar; removing, after removing the oxide material from the pillar, the first layer of protective material and the second layer of protective material; and depositing a conductive liner along sidewalls of the pillar, the sidewalls of the cavity, and sidewalls of the recess.

Aspect 9: The method, apparatus, or non-transitory computer-readable medium of aspect 8, further including operations, features, circuitry, logic, means, or instructions, or any combination thereof for forming, after removing the sacrificial material from the recess, an oxide liner along the sidewalls of the cavity and the sidewalls of the recess, where the oxide liner covers a top portion of the oxide material in the pillar, and where the second layer of protective material is formed after the oxide liner and etching, via a punch etch, the second layer of protective material and the oxide liner to remove a portion of the second layer of protective material and a portion of the oxide liner along the top portion of the oxide material in the pillar, where remaining portions of the second layer of protective material and the oxide liner remain along the sidewalls of the cavity, and where removing the oxide material from the pillar is based at least in part on the etching.

Aspect 10: The method, apparatus, or non-transitory computer-readable medium of aspect 9, where removing the oxide material includes operations, features, circuitry, logic, means, or instructions, or any combination thereof for removing, as part of an oxide exhume after etching the second layer of protective material and the oxide liner, the oxide material via the cavity, where a portion of the oxide liner within the recess is removed based at least in part on the oxide exhume.

Aspect 11: The method, apparatus, or non-transitory computer-readable medium of any of aspects 8 through 10, further including operations, features, circuitry, logic, means, or instructions, or any combination thereof for removing, after removing the oxide material, the first layer of protective material, and the second layer of protective material, a portion of a nitride liner from the recess to increase a size of the recess before depositing the conductive liner, where the pillar further includes the nitride liner positioned between the sidewalls of the first stack and the first layer of protective material, and where the portion of the nitride liner is positioned between the sidewalls of the first stack and the recess after the recess is formed and before the portion is removed.

Aspect 12: The method, apparatus, or non-transitory computer-readable medium of any of aspects 8 through 11, where the pillar further includes a nitride liner positioned between the sidewalls of the first stack and the first layer of protective material; after the recess is formed and the second layer of protective material is removed, a portion of the nitride liner is exposed along the sidewalls of the recess; and the conductive liner is deposited along the portion of the nitride liner within the recess.

Aspect 13: The method, apparatus, or non-transitory computer-readable medium of any of aspects 8 through 12, further including operations, features, circuitry, logic, means, or instructions, or any combination thereof for etching, in accordance with a wet etch process after depositing the conductive liner, a portion of the conductive liner to reduce a width of the conductive liner alone the sidewalls of the pillar, the sidewalls of the cavity, and sidewalls of the recess, where the sidewalls of the recess include at least three segments.

Aspect 14: The method, apparatus, or non-transitory computer-readable medium of any of aspects 8 through 13, further including operations, features, circuitry, logic, means, or instructions, or any combination thereof for depositing, after depositing the conductive liner, the oxide material in the pillar, the recess, and at least a portion of the cavity and depositing, after depositing the oxide material, a conductive material, where the conductive material fills a second portion of the cavity between the oxide material and a top layer of the second stack.

Aspect 15: The method, apparatus, or non-transitory computer-readable medium of any of aspects 8 through 14, further including operations, features, circuitry, logic, means, or instructions, or any combination thereof for performing, after depositing the conductive liner, a metallization process to remove a set of nitride layers from the first stack and the second stack to form a set of cavities and deposit a metal in each cavity of the set of cavities to form the metal layers, the metal layers forming a set of word lines.

Aspect 16: The method, apparatus, or non-transitory computer-readable medium of any of aspects 8 through 15, further including operations, features, circuitry, logic, means, or instructions, or any combination thereof for forming a set of memory cells at each of the oxide layers and the metal layers, where the conductive liner includes a memory channel for the set of memory cells.

It should be noted that the described methods include possible implementations, and that the operations and the steps may be rearranged or otherwise modified and that other implementations are possible. Further, portions from two or more of the methods may be combined.

An apparatus is described. The following provides an overview of aspects of the apparatus as described herein:

Aspect 17: An apparatus, including: a stack including a plurality of oxide layers and a plurality of metal layers; and a pillar extending through the stack, the pillar including a first width in a first level of the stack, a second width in a second level of the stack, and one or more third widths in a third level of the stack, the third level of the stack including a junction between the first level of the stack and the second level of the stack, where the pillar includes: a conductive liner that extends continuously along a sidewall of the stack, the conductive liner including a first segment along the sidewall in the first level of the stack, a second segment along the sidewall in the second level of the stack, and a third segment that curves along the sidewall in the third level of the stack, the third segment of the conductive liner coupled with a first oxide layer of the plurality of oxide layers in the first level of the stack, a nitride liner, and an oxide liner, where the oxide liner extends between the nitride liner and the second segment of the conductive liner in the second level of the stack; and an oxide material that extends through the second level of the pillar, the third level of the pillar, and a portion of the first level of the pillar, where the conductive liner is positioned between the oxide material and the sidewall of the stack.

Aspect 18: The apparatus of aspect 17, where the pillar further includes: a second conductive liner that extends continuously along a second sidewall of the stack, the second conductive liner including a respective first segment along the second sidewall in the first level of the stack, a respective second segment along the second sidewall in the second level of the stack, and a respective third segment that curves along the second sidewall in the third level of the stack, where the oxide material is between the conductive liner and the second conductive liner.

Aspect 19: The apparatus of any of aspects 17 through 18, where the pillar further includes: a conductive material positioned above the oxide material in the first level of the pillar.

Aspect 20: The apparatus of any of aspects 17 through 19, where a plurality of memory cells coupled with the plurality of oxide layers, the plurality of metal layers, and the pillar.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to a condition of moving from an open-circuit relationship between components in which signals are not presently capable of being communicated between the components over a conductive path to a closed-circuit relationship between components in which signals are capable of being communicated between components over the conductive path. If a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other if the switch is open. If a controller isolates two components, the controller affects a change that prevents signals from flowing between the components using a conductive path that previously permitted signals to flow.

The term “layer” or “level” used herein refers to a stratum or sheet of a geometrical structure (e.g., relative to a substrate). Each layer or level may have three dimensions (e.g., height, width, and depth) and may cover at least a portion of a surface. For example, a layer or level may be a three dimensional structure where two dimensions are greater than a third, e.g., a thin-film. Layers or levels may include different elements, components, or materials, or combinations thereof. In some examples, one layer or level may be composed of two or more sublayers or sublevels.

As used herein, the term “electrode” may refer to an electrical conductor, and in some examples, may be employed as an electrical contact to a memory cell or other component of a memory array. An electrode may include a trace, wire, conductive line, conductive layer, or the like that provides a conductive path between elements or components of a memory array.

The terms “if,” “when,” “based on,” or “based at least in part on” may be used interchangeably. In some examples, if the terms “if,” “when,” “based on,” or “based at least in part on” are used to describe a conditional action, a conditional process, or connection between portions of a process, the terms may be interchangeable.

The term “in response to” may refer to one condition or action occurring at least partially, if not fully, as a result of a previous condition or action. For example, a first condition or action may be performed and second condition or action may at least partially occur as a result of the previous condition or action occurring (whether directly after or after one or more other intermediate conditions or actions occurring after the first condition or action).

Additionally, the terms “directly in response to” or “in direct response to” may refer to one condition or action occurring as a direct result of a previous condition or action. In some examples, a first condition or action may be performed and second condition or action may occur directly as a result of the previous condition or action occurring independent of whether other conditions or actions occur. In some examples, a first condition or action may be performed and second condition or action may occur directly as a result of the previous condition or action occurring, such that no other intermediate conditions or actions occur between the earlier condition or action and the second condition or action or a limited quantity of one or more intermediate steps or actions occur between the earlier condition or action and the second condition or action. Any condition or action described herein as being performed “based on,” “based at least in part on,” or “in response to” some other step, action, event, or condition may additionally, or alternatively (e.g., in an alternative example), be performed “in direct response to” or “directly in response to” such other condition or action unless otherwise specified.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorus, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as an n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” if a voltage greater than or equal to the transistor's threshold voltage is applied to the transistor gate. The transistor may be “off” or “deactivated” if a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

The functions described herein may be implemented in hardware, software executed by a processing system (e.g., one or more processors, one or more controllers, control circuitry processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A method, comprising:
forming a first stack comprising a set of oxide layers and metal layers;
forming a pillar that extends through the first stack, the pillar comprising an oxide material and a first layer of protective material, wherein the first layer of protective material is positioned between the oxide material of the pillar and sidewalls of the first stack;
etching a portion of the oxide material and a portion of the first layer of protective material to form a recess in a first layer of the pillar;
forming a sacrificial material in the recess;
forming a second stack of oxide layers and metal layers positioned above the first stack and the sacrificial material, wherein a second layer of protective material extends along sidewalls of a cavity that extends through the second stack;
removing, via the cavity, the sacrificial material and the oxide material from the recess and the pillar, respectively;
removing, after removing the sacrificial material and the oxide material, the first layer of protective material and the second layer of protective material from the pillar and the sidewalls of the cavity, respectively; and
depositing a conductive liner along sidewalls of the pillar, the sidewalls of the cavity, and sidewalls of the recess.

2. The method of claim 1, further comprising:
forming an oxide liner along the sidewalls of the cavity and along a first surface of the sacrificial material;
forming, after forming the oxide liner, the second layer of protective material along the oxide liner; and
etching, via a punch etch, the second layer of protective material and the oxide liner to remove a portion of the second layer of protective material and a portion of the oxide liner along the first surface of the sacrificial material, wherein remaining portions of the second layer of protective material and the oxide liner remain along the sidewalls of the cavity, and wherein removing the sacrificial material via the cavity is based at least in part on removing the portion of the second layer of protective material and the portion of the oxide liner along the first surface of the sacrificial material.

3. The method of claim 2, wherein removing the oxide material comprises:
removing, as part of an oxide exhume after removing the sacrificial material, the oxide material via the cavity, wherein a portion of the oxide liner within the recess is removed based at least in part on the oxide exhume.

4. The method of claim 1, further comprising:
etching, in accordance with a wet etch process after depositing the conductive liner, a portion of the conductive liner to reduce a width of the conductive liner along the sidewalls of the pillar, the sidewalls of the cavity, and sidewalls of the recess, wherein the sidewalls of the recess comprise curved sidewalls.

5. The method of claim 1, further comprising:
depositing, after depositing the conductive liner, the oxide material in the pillar, the recess, and at least a portion of the cavity; and
depositing, after depositing the oxide material, a conductive material, wherein the conductive material fills a second portion of the cavity between the oxide material and a top layer of the second stack.

6. The method of claim 1, further comprising:
performing, after depositing the conductive liner, a metallization process to remove a set of nitride layers from the first stack and the second stack to form a set of cavities and deposit a metal in each cavity of the set of cavities to form the metal layers, the metal layers forming a set of word lines.

7. The method of claim 1, further comprising:
forming a set of memory cells at each layer of the oxide layers and the metal layers, wherein the conductive liner comprises a memory channel for the set of memory cells.

8. A method, comprising:
forming a first stack comprising a set of oxide layers and metal layers;
forming a pillar that extends through the first stack, the pillar comprising an oxide material and a first layer of protective material, wherein the first layer of protective material is positioned between the oxide material of the pillar and sidewalls of the first stack;
etching a portion of the oxide material and a portion of the first layer of protective material to form a recess in a first layer of the pillar;
forming a sacrificial material in the recess;
forming a second stack of oxide layers and metal layers positioned above the first stack and the sacrificial material;
forming a cavity through the second stack and a portion of the sacrificial material;
removing, via the cavity, the sacrificial material from the recess;
depositing a second protective material to form a second layer of protective material along sidewalls of the cavity and the recess;
removing, via the cavity, the oxide material from the pillar;
removing, after removing the oxide material from the pillar, the first layer of protective material and the second layer of protective material; and
depositing a conductive liner along sidewalls of the pillar, the sidewalls of the cavity, and sidewalls of the recess.

9. The method of claim 8, further comprising:
forming, after removing the sacrificial material from the recess, an oxide liner along the sidewalls of the cavity and the sidewalls of the recess, wherein the oxide liner covers a top portion of the oxide material in the pillar, and wherein the second layer of protective material is formed after the oxide liner; and
etching, via a punch etch, the second layer of protective material and the oxide liner to remove a portion of the second layer of protective material and a portion of the oxide liner along the top portion of the oxide material in the pillar, wherein remaining portions of the second layer of protective material and the oxide liner remain along the sidewalls of the cavity, and wherein removing the oxide material from the pillar is based at least in part on the etching.

10. The method of claim 9, wherein removing the oxide material comprises:
removing, as part of an oxide exhume after etching the second layer of protective material and the oxide liner, the oxide material via the cavity, wherein a portion of the oxide liner within the recess is removed based at least in part on the oxide exhume.

11. The method of claim 8, further comprising:
removing, after removing the oxide material, the first layer of protective material, and the second layer of protective material, a portion of a nitride liner from the recess to increase a size of the recess before depositing the conductive liner, wherein the pillar further comprises the nitride liner positioned between the sidewalls of the first stack and the first layer of protective material, and wherein the portion of the nitride liner is positioned between the sidewalls of the first stack and the recess after the recess is formed and before the portion is removed.

12. The method of claim 8, wherein:
the pillar further comprises a nitride liner positioned between the sidewalls of the first stack and the first layer of protective material;
after the recess is formed and the second layer of protective material is removed, a portion of the nitride liner is exposed along the sidewalls of the recess; and
the conductive liner is deposited along the portion of the nitride liner within the recess.

13. The method of claim 8, further comprising:
etching, in accordance with a wet etch process after depositing the conductive liner, a portion of the conductive liner to reduce a width of the conductive liner alone the sidewalls of the pillar, the sidewalls of the cavity, and sidewalls of the recess, wherein the sidewalls of the recess comprise at least three segments.

14. The method of claim 8, further comprising:
depositing, after depositing the conductive liner, the oxide material in the pillar, the recess, and at least a portion of the cavity; and
depositing, after depositing the oxide material, a conductive material, wherein the conductive material fills a second portion of the cavity between the oxide material and a top layer of the second stack.

15. The method of claim 8, further comprising:
performing, after depositing the conductive liner, a metallization process to remove a set of nitride layers from the first stack and the second stack to form a set of cavities and deposit a metal in each cavity of the set of cavities to form the metal layers, the metal layers forming a set of word lines.

16. The method of claim 8, further comprising:
forming a set of memory cells at each of the oxide layers and the metal layers, wherein the conductive liner comprises a memory channel for the set of memory cells.

17. An apparatus, comprising:
a stack comprising a plurality of oxide layers and a plurality of metal layers; and
a pillar extending through the stack, the pillar comprising a first width in a first level of the stack, a second width in a second level of the stack, and one or more third widths in a third level of the stack, the third level of the stack comprising a junction between the first level of the stack and the second level of the stack, wherein the pillar comprises:
a conductive liner that extends continuously along a sidewall of the stack, the conductive liner comprising a first segment along the sidewall in the first level of the stack, a second segment along the sidewall in the second level of the stack, and a third segment that curves along the sidewall in the third level of the stack, the third segment of the conductive liner coupled with a first oxide layer of the plurality of oxide layers in the first level of the stack, a nitride liner, and an oxide liner, wherein the oxide liner extends between the nitride liner and the second segment of the conductive liner in the second level of the stack; and
an oxide material that extends through the second level of the pillar, the third level of the pillar, and a portion of the first level of the pillar, wherein the conductive liner is positioned between the oxide material and the sidewall of the stack.

18. The apparatus of claim 17, wherein the pillar further comprises:
a second conductive liner that extends continuously along a second sidewall of the stack, the second conductive liner comprising a respective first segment along the second sidewall in the first level of the stack, a respective second segment along the second sidewall in the second level of the stack, and a respective third segment that curves along the second sidewall in the third level of the stack, wherein the oxide material is between the conductive liner and the second conductive liner.

19. The apparatus of claim 17, wherein the pillar further comprises:
a conductive material positioned above the oxide material in the first level of the pillar.

20. The apparatus of claim 17, wherein a plurality of memory cells coupled with the plurality of oxide layers, the plurality of metal layers, and the pillar.
